(19) United States
(12) Patent Application Publication
(10) Pub. No.: US 2025/0062288 A1
(43) Pub. Date: Feb. 20, 2025

(54) SEMICONDUCTOR PACKAGE HAVING CHIP STACK STRUCTURE

(71) Applicant: SK hynix Inc., Icheon-si Gyeonggi-do (KR)

(72) Inventor: Seong Ju LEE, Icheon-si Gyeonggi-do (KR)

(73) Assignee: SK hynix Inc., Icheon-si Gyeonggi-do (KR)

(21) Appl. No.: 18/770,004

(22) Filed: Jul. 11, 2024

Related U.S. Application Data
(60) Provisional application No. 63/520,571, filed on Aug. 18, 2023.

(51) Int. Cl. H01L 25/065; H01L 23/00; H10B 80/00

(52) U.S. Cl. CPC H01L 25/0657; H01L 24/06; H01L 24/48; H01L 24/73; H10B 80/00; H01L 24/32; H01L 2224/06131; H01L 2224/32145; H01L 2224/32225; H01L 2224/48145; H01L 2224/48227; H01L 2224/73265; H01L 2225/06506; H01L 2225/0651; H01L 2225/06562; H01L 2924/1436

(57) ABSTRACT

An embodiment of the disclosed technology provides a semiconductor package including: a substrate; a first chip and a second chip stacked on the substrate, each of the first chip and the second chip including a slice command/address reception pad, a slice command/address transmission pad, a slice data pad, an input buffer connected to the slice command/address reception pad, an output buffer connected to the slice command/address transmission pad and an input/output buffer connected to the slice data pad; a first connection member connecting the slice command/address transmission pad of the first chip to the slice command/address reception pad of the second chip; and a second connection member connecting the slice data pad of the first chip to the slice data pad of the second chip.

### CROSS-REFERENCES TO RELATED APPLICATION

The present application is a continuation-in-part application of and claims the benefit under 35 U.S.C. § 119 (e) of U.S. Provisional application No. 63/520,571, filed on Aug. 18, 2023, which application is incorporated herein by reference in its entirety.

### BACKGROUND

### 1. Technical Field

Various embodiments generally relate to a semiconductor package having a chip stack structure.

### 2. Related Art

In accordance with the demand for high integration, the degree of integration has been improved through a scale-down method of reducing line widths, but as the scale-down technology reaches its limits, a chip stack structure has been attracting attention.

The chip stack structure includes a plurality of chips stacked on each other. The plurality of chips in the chip stack structure may transmit and receive signals to and from other devices through bonding wires.

### SUMMARY

In an embodiment, a semiconductor package may include: a substrate; a first chip and a second chip stacked on the substrate, each of the first chip and the second chip including a slice command/address reception pad, a slice command/address transmission pad, a slice data pad, an input buffer connected to the slice command/address reception pad, an output buffer connected to the slice command/address transmission pad and an input/output buffer connected to the slice data pad; a first connection member connecting the slice command/address transmission pad of the first chip to the slice command/address reception pad of the second chip; and a second connection member connecting the slice data pad of the first chip to the slice data pad of the second chip.

In an embodiment, a semiconductor package may include: a substrate; a master chip and a slave chip stacked on the substrate, each of the master chip and the slave chip including a slice command/address reception pad, a slice command/address transmission pad, an input buffer connected to the slice command/address reception pad and an output buffer connected to the slice command/address transmission pad; and a first connection member connecting the slice command/address transmission pad of the master chip to the slice command/address reception pad of the slave chip.

In an embodiment, a semiconductor package may include a substrate; a master chip stacked on the substrate and comprising a first slice command/address transmission pad connected to a first output buffer; a first slave chip stacked on the master chip and comprising a second slice command/address reception pad connected to a second input buffer; and a first connection member connecting the first slice command/address transmission pad to the second slice command/address reception pad.

### BRIEF DESCRIPTION OF THE DRAWINGS

FIG. 1 is a block diagram of a memory system including a semiconductor package based on an embodiment of the disclosed technology.

FIG. 2 is a perspective view of a semiconductor package based on an embodiment of the disclosed technology.

FIG. 3 is a cross-sectional view taken along the line I-I′ of FIG. 2.

FIG. 4 is a cross-sectional view taken along the line II-II′ of FIG. 2.

FIG. 5 to FIG. 8 are diagrams illustrating data input/output paths of semiconductor packages based on embodiments of the disclosed technology.

FIG. 9, FIG. 10, FIG. 12 and FIG. 14 are perspective views of semiconductor packages based on embodiments of the disclosed technology.

FIG. 11 is a cross-sectional view taken along the line III-III′ of FIG. 10.

FIG. 13 is a perspective view illustrating a substrate, a first chip and connection members connecting the substrate and the first chip in FIG. 12.

FIG. 15 is a view illustrating a semiconductor package based on an embodiment of the disclosed technology.

FIG. 16 is a perspective view illustrating an example of the semiconductor package of FIG. 15.

FIG. 17 is a cross-sectional view taken along the line IV-IV′ of FIG. 16 in accordance with an embodiment.

FIG. 18 is a view illustrating a semiconductor package based on an embodiment of the disclosed technology.

FIG. 19 is a perspective view illustrating an example of a semiconductor package of FIG. 18.

FIG. 20 is a cross-sectional view taken along the line V-V′ of FIG. 19 in accordance with an embodiment.

FIG. 21 and FIG. 22 are perspective views illustrating examples of a semiconductor package of FIG. 15.

FIG. 23 is a cross-sectional view taken along the line VI-VI′ of FIG. 22 in accordance with an embodiment.

FIG. 24 is a perspective view illustrating an example of a semiconductor package of FIG. 18.

FIG. 25 is a cross-sectional view taken along the line VII-VII′ of FIG. 24 in accordance with an embodiment.

### DETAILED DESCRIPTION

Embodiments of the present disclosure are described in detail with reference to the accompanying drawings. When an indefinite or definite article refers to a singular noun, for example, “a,” “an,” and “the,” this reference includes a plural of that noun unless specifically stated otherwise.

Terms such as “first” and “second” are used to differentiate one component from another component but do not imply size, order, sequence, priority, quantity, or importance of the components. The cross-hatching throughout the figures illustrates corresponding or similar areas between the figures rather than indicating the materials for the areas.

When one element is identified as “connected” or “coupled” to another element, the elements may be connected or coupled directly or through at least one intervening element between the elements. When two elements are identified as “directly connected” or “directly coupled,” one element is directly connected or directly coupled to the other element without an intervening element between the two elements. When one element is identified as “on,” “over,” or “under” another element, the elements may directly contact each other or an intervening element may be disposed between the elements.

In descriptions related to time flow of an operating method or a fabricating method, when pre and post relationships in terms of time or pre and post relationships in terms of flow are described, for example, utilizing “after,” “following,” “next,” “before,” and similar terms, non-continuous examples are included unless “immediately” or “directly” is used. Terms such as “top,” “bottom,” “underlying,” “overhang,” “on,” “side,” “column,” “row,” “outermost,” “underlying,” “level,” and other terms implying relative spatial relationship or orientation are utilized only for the purpose of ease of description or reference to a drawing and are not otherwise limiting.

When a numerical value for a component or its corresponding information for example, level, and so forth is stated, even without separate explicit description, the numerical value or its corresponding information includes an error range that may be caused by various factors as known in the industry, for example, a process variable, an internal or external shock, noise, and so forth.

Various embodiments of the disclosed technology are described in detail with reference to the accompanying drawings.

Various embodiments are directed to a semiconductor package with a chip stack structure.

According to the embodiments, a semiconductor package may be fabricated having a chip stack structure with a plurality of chips that can transmit and receive signals to and from other devices through bonding wires.

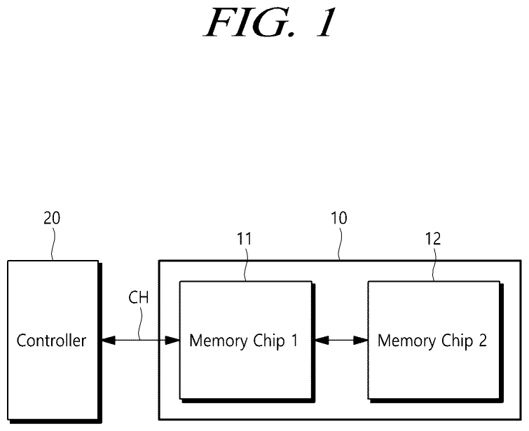

FIG. 1 is a block diagram of a memory system including a semiconductor package based on an embodiment of the disclosed technology.

Referring to FIG. 1, a semiconductor package 10 may be connected to an external device 20 through a channel CH.

The external device 20 may control overall operations of the semiconductor package 10, for example, a read operation and a write operation, in response to a request of a host (not shown). The external device 20 may include a memory controller or a processor.

The semiconductor package 10 may include a first chip 11 and a second chip 12. An example in which the semiconductor package 10 includes two semiconductor chips is described, although the disclosed technology is not limited thereto. The semiconductor package 10 may include at least three semiconductor chips. Semiconductor chips included in the semiconductor package 10 may be referred to as slices.

The first and second chips 11 and 12 may include various types of memories. For example, each of the first and second chips 11 and 12 may include a dynamic random access memory (DRAM). The disclosed technology is not limited thereto, and each of the first and second chips 11 and 12 may include a volatile memory, such as an SRAM (static RAM) or a nonvolatile memory, such as a NAND flash, a resistive RAM (RRAM), a phase-change RAM (PRAM), a magnetoresistive RAM (MRAM) and a ferroelectric RAM (FRAM).

The first chip 11 may operate as a master chip, and the second chip 12 may operate as a slave chip. The first chip 11 and the second chip 12 may function in such a manner that they receive the same chip select signal and a specific layer of the first chip 11 and the second chip 12 may be accessed by an address signal. In another embodiment, the first chip 11 and the second chip 12 may function as different logical ranks.

The first chip 11 may be connected to the channel CH to interface with the external device 20 through the channel CH, may exchange data with the external device 20, and may receive a command, an address, and a clock from the external device 20.

The first chip 11 may be connected to the second chip 12 to interface with the second chip 12, may exchange data with the second chip 12, and may provide a command and an address to the second chip 12.

The first chip 11 may parallelize write data input from the external device 20. The first chip 11 may serialize data read from the first chip 11 or the second chip 12 and may output the data to the external device 20. The first chip 11 may generate a slice command by decoding a command input from the external device 20. The first chip 11 may generate a slice address by decoding an address input from the external device 20. The slice command may include a read command and a write command. The slice address may include a bank address, a row address, and a column address.

The first chip 11 may output parallelized write data to the second chip 12 and may receive read data from the second chip 12. The first chip 11 may provide a slice command and a slice address to the second chip 12.

The second chip 12 may be connected to the first chip 11 to interface with the first chip 11. Only the first chip 11 may be connected to the channel CH, and the second chip 12 might not be connected to the channel CH. Only the first chip 11 may face the load of the channel CH and have a channel load, and the second chip 12 may be load-decoupled from the channel CH. Accordingly, as the loading factor of the semiconductor package 10 is maintained to be low, timing and bus speed may be improved, and data input/output speed may be improved. In addition, signal integrity may be improved, and power consumption may be reduced.

The disclosed technology proposes a semiconductor package in which signals are transmitted between slices using bonding wires.

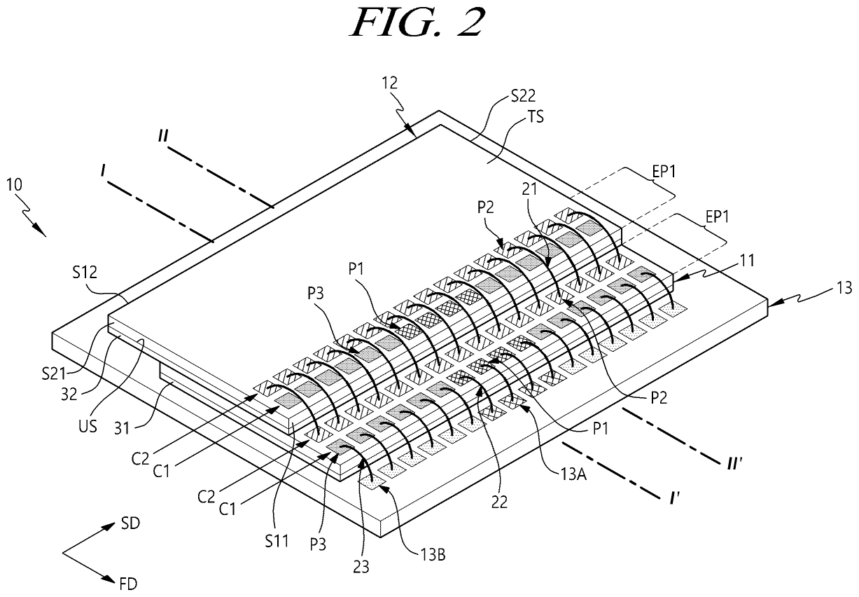

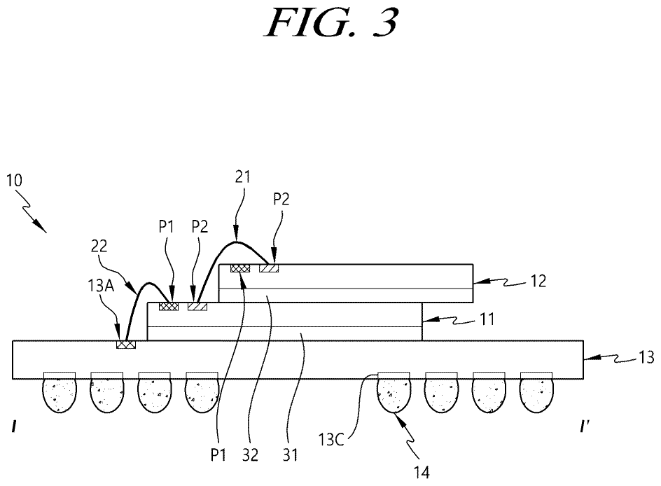

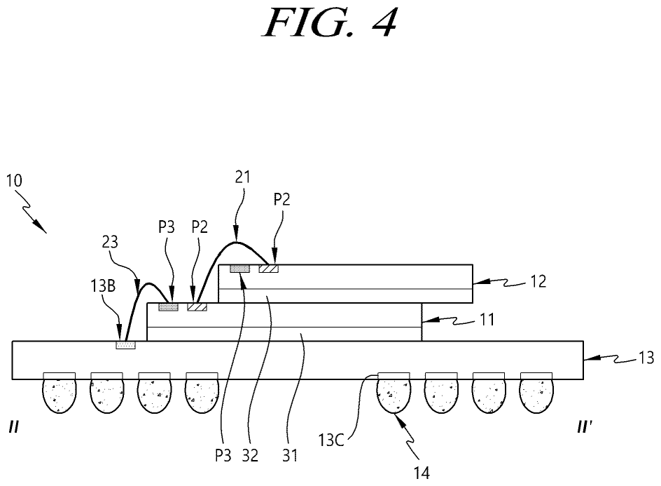

FIG. 2 is a perspective view of a semiconductor package based on an embodiment of the disclosed technology, FIG. 3 is a cross-sectional view taken along the line I-I′ of FIG. 2, and FIG. 4 is a cross-sectional view taken along the line II-II′ of FIG. 2.

Referring to FIG. 2 to FIG. 4, a semiconductor package 10 may include a substrate 13, a first chip 11 and a second chip 12. The first and second chips 11 and 12 are stacked on the substrate 13.

The substrate 13 may include a circuit and/or wiring structure for electrically connecting the first chip 11 to an external device. For example, the substrate 13 may include a printed circuit board (PCB), an interposer, or a redistribution layer.

A plurality of top substrate pads 13A and 13B may be disposed on the top surface of the substrate 13. When the substrate 13 is connected to the first chip 11 through bonding wires, the top substrate pads 13A and 13B may include bond fingers. Bottom substrate pads 13C for connecting with external connection terminals 14 may be disposed on the bottom surface of the substrate 13. When the external connection terminals 14 are solder balls, the bottom substrate pads 13C may include ball lands. Each of the top substrate pads 13A and 13B may be electrically connected to a corresponding bottom substrate pad 13C through the circuit and/or wiring structure in the substrate 13.

The first chip 11 may be disposed on the substrate 13, and the second chip 12 may be disposed on the first chip 11. A first adhesive layer 31 may be disposed between the substrate 13 and the first chip 11 to attach the first chip 11 to the substrate 13. A second adhesive layer 32 may be disposed between the first chip 11 and the second chip 12 to attach the first chip 11 to the second chip 12.

The first chip 11 and the second chip 12 may have structures that are physically the same as each other. The first chip 11 and the second chip 12 may be the same type of chip. The first chip 11 and the second chip 12 may be the same size.

Each of the first and second chips 11 and 12 may have a top surface TS on which pads P1, P2, and P3 are disposed, a bottom surface US that is on the opposite side of the top surface TS, and side surfaces S11, S12, S21 and S22 that connect the top surface TS to the bottom surface US. The side surfaces S11, S12, S21 and S22 may include two side surfaces S11 and S12 that are on opposite sides of each other in a first direction FD parallel to the top surface of the substrate 13, and two side surfaces S21 and S22 that are on opposite sides of each other in a second direction SD parallel to the top surface of the substrate 13 and perpendicular to the first direction FD. Hereinafter, the two side surfaces S11 and S12 that are on opposite sides of each other in the first direction FD will be referred to as a first side surface S11 and a second side surface S12.

The pads P1, P2, and P3 may include a plurality of external signal pads P1, a plurality of slice signal pads P2, and a plurality of power pads P3.

The external signal pads P1 may include an external data pad, an external command/address (CA) pad, an external clock pad, and so on. The slice signal pads P2 may include a slice data pad, a slice command pad, a slice address pad, and so on. Optionally, the slice signal pads P2 may further include a slice power pad.

Each of the first and second chips 11 and 12 may include first and second pad columns C1 and C2 that are located in a first edge portion EP1 including the first side surface S11. In each of the first and second chips 11 and 12, the first pad column C1 may be located between the first side surface S11 and the second pad column C2. For instance, each chip may include a plurality of pad columns, and among the pad columns included in each chip, the first pad column C1 may be an outermost pad column that is closest to the first side surface S11 and the second pad column C2 may be a pad column that is adjacent to the first pad column C1 but farther from the first side surface S11 than the first pad column C1.

In each of the first and second chips 11 and 12, the external signal pads P1 may be included in the first pad column C1, and the slice signal pads P2 may be included in the second pad column C2.

The second chip 12 may be offset with respect to the first chip 11 and exposes or facilitates access to the first and second pad columns C1 and C2 of the first chip 11.

In a planar view, the first pad column C1 of the first chip 11 may be disposed between the top substrate pads 13A and 13B of the substrate 13 and the second pad column C2 of the first chip 11, and the second pad column C2 of the first chip 11 may be disposed between the first pad column C1 of the first chip 11 and the second chip 12. The first pad column C1 of the first chip 11 may be adjacent to the top substrate pads 13A and 13B of the substrate 13, and the second pad column C2 of the first chip 11 may be adjacent to the second chip 12.

The slice signal pads P2 of the first chip 11 and the slice signal pads P2 of the second chip 12 may be connected to each other through first connection members 21. Each of the slice signal pads P2 of the first chip 11 may be connected to a corresponding slice signal pad P2 of the second chip 12 through the first connection member 21. The first connection members 21 may include bonding wires.

First top substrate pads 13A of the substrate 13 and the external signal pads P1 of the first chip 11 may be connected to each other through second connection members 22. Each of the external signal pads P1 of the first chip 11 may be connected to a corresponding first top substrate pad 13A through the second connection member 22. The second connection members 22 may include bonding wires.

Each of the external signal pads P1 of the first chip 11 may contact a bonding wire that is connected to the substrate 13. Each of the external signal pads P1 of the second chip 12 might not contact a bonding wire. The external signal pads P1 of the second chip 12 may be in a disabled state.

In each of the first and second chips 11 and 12, the power pads P3 may be included in the first pad column C1. The power pads P3 may be disposed in the same pad column as the external signal pads P1. The disposition of the external signal pads P1 and the power pads P3 may be variously changed in the first pad column C1.

Second top substrate pads 13B of the substrate 13 and the power pads P3 of the first chip 11 may be connected to each other through third connection members 23. Each of the power pads P3 of the first chip 11 may be connected to a corresponding second top substrate pad 13B through the third connection member 23. The third connection members 23 may include bonding wires. The first chip 11 may be supplied with power from the substrate 13 through the third connection members 23. The power may include VDD, VSS, VDDQ, and VSSQ.

The power pads P3 of the first chip 11 may contact bonding wires that are connected to the substrate 13. The power pads P3 of the second chip 12 might not be connected to bonding wires. The power pads P3 of the second chip 12 might not contact bonding wires that are connected to the substrate 13. The power pads P3 of the second chip 12 may be in a disabled state.

As the external signal pads P1 and the power pads P3 of the first chip 11 are disposed in the first pad column C1 that is adjacent to the top substrate pads 13A and 13B of the substrate 13 and the slice signal pads P2 of the first chip 11 are disposed in the second pad column C2 that is adjacent to the second chip 12, the first connection members 21 and the second and third connection members 22 and 23 may be disposed on opposing sides, respectively, of the first edge portion EP1 of the first chip 11. That is to say, the first connection members 21 may be disposed on one side of the first edge portion EP1 of the first chip 11, and the second and third connection members 22 and 23 may be disposed on the other side of the first edge portion EP1 of the first chip 11.

Because the second and third connection members 22 and 23 are disposed on only one side of the first edge portion EP1 of the first chip 11, the second and third connection members 22 and 23 might not be disposed on the other side of the first edge portion EP1 of the first chip 11. Accordingly, a large number of first connection members 21 may be disposed on the other side of the first edge portion EP1 of the first chip 11 without being restricted in space due to the second and third connection members 22 and 23. Therefore, even when the number of slice signals is large, it is possible to transmit the slice signals by using the first connection members 21, for example, bonding wires.

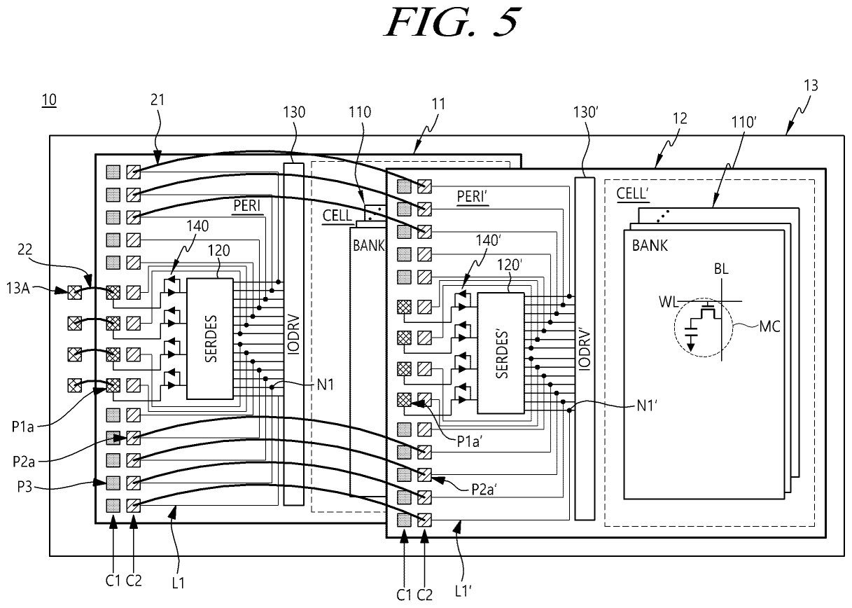

FIG. 5 to FIG. 8 are diagrams illustrating data input/output paths of semiconductor packages based on embodiments of the disclosed technology. Hereafter, for the sake of simplicity in explanation, repeated description for the same configuration between different embodiments will be omitted, and only differences will be mainly described.

Referring to FIG. 5, a first chip 11 may include a cell region CELL and a peripheral region PERI. A second chip 12 may include a cell region CELL′ and a peripheral region PERI′.

A memory cell array 110 may be disposed in the cell region CELL of the first chip 11. A memory cell array 110′ may be disposed in the cell region CELL′ of the second chip 12. Each of the memory cell arrays 110 and 110′ may include a plurality of memory banks BANKs. The number of memory banks included in each of the memory cell arrays 110 and 110′ may be, for example, 2, 4, 8, 16, 32, or any number that is a multiple of 2. Each memory bank BANK may include a plurality of word lines WL, a plurality of bit lines BL, and a plurality of memory cells MC. The memory cells MC may be disposed at intersections of the word lines WL and the bit lines BL. For the sake of simplicity in illustration, FIG. 5 illustrates only one word line WL, only one bit line BL and only one memory cell MC.

Although not shown, each of the first and second chips 11 and 12 may include a row decoder that serves to select a word line and a column decoder that serves to select a bit line. The row decoder and the column decoder may be provided for each memory bank BANK. The row decoder and the column decoder of the first chip 11 may be disposed in the cell region CELL, and the row decoder and the column decoder of the second chip 12 may be disposed in the cell region CELL′, although the disclosed technology is not limited thereto.

In FIG. 5, the reference symbol P1a denotes external data pads of the first chip 11, and the reference symbol P2a denotes slice data pads of the first chip 11. The reference symbol P1a′ denotes external data pads of the second chip 12, and the reference symbol P2a′ denotes slice data pads of the second chip 12. Hereafter, for the sake of convenience in explanation, the external data pads P1a and P1a′ will be referred to as first pads, and the slice data pads P2a and P2a′ will be referred to as second pads. The plurality of first pads external data pads P1a may be included in a first pad column C1 of the first chip 11, and the plurality of slice data pads P2a may be included in a second pad column C2 of the first chip 11. The plurality of external data pads P1a′ may be included in a first pad column C1 of the second chip 12, and the plurality of slice data pads P2a′ may be included in a second pad column C2 of the second chip 12. Each of the first and second chips 11 and 12 may further include an external command/address (CA) pad and an external clock pad in the first pad column C1 and may further include a slice command pad and a slice address pad in the second pad column C2. However, illustration of these pads has been omitted for the sake of convenience in explanation.

The peripheral region PERI may be located in a chip edge region of the first chip 11 and may include an edge portion in which the first and second pad columns C1 and C2 are located. The peripheral region PERI′ may be located in a chip edge region of the second chip 12 and may include an edge portion in which the first and second pad columns C1 and C2 are located. Each of the first and second chips 11 and 12 may have an edge peripheral structure.

A peripheral circuit of the first chip 11 may be disposed in the peripheral region PERI. The peripheral circuit of the first chip 11 may include a serializer-deserializer (SERDES) 120, an input/output driver (IODRV) 130, and a plurality of input/output buffers 140. A peripheral circuit of the second chip 12 may be disposed in the peripheral region PERI′. The peripheral circuit of the second chip 12 may include a serializer-deserializer (SERDES′) 120′, an input/output driver (IODRV′) 130′, and a plurality of input/output buffers 140′.

In the first chip 11, the serializer-deserializer 120 may be connected between the first pads P1a and first nodes N1. The serializer-deserializer 120 may be connected to the first pads P1a through the input/output buffers 140. In the second chip 12, the serializer-deserializer 120′ may be connected between the first pads P1a′ and first nodes N1′. The serializer-deserializer 120′ may be connected to the first pads P1a′ through the input/output buffers 140′.

The serializer-deserializer 120 of the first chip 11 may receive write data from an external device through the first pads P1a of the first chip 11. The serializer-deserializer 120 may parallelize the received write data, and may output the parallelized write data to the first nodes N1 of the first chip 11. For instance, the serializer-deserializer 120 of the first chip 11 may receive four 16-bit data input through four first pads P1a, may parallelize the four 16-bit data into 64-bit data, and may output the 64-bit data to the first nodes N1 of the first chip 11. Write data input from the external device to the first pads P1a of the first chip 11 may pass through the input/output buffers 140 of the first chip 11, may be parallelized in the serializer-deserializer 120 of the first chip 11, and may be output to the first nodes N1 of the first chip 11.

The serializer-deserializer 120 of the first chip 11 may receive data read from the cell region CELL of the first chip 11 or the cell region CELL′ of the second chip 12 and may serialize the data. For instance, the serializer-deserializer 120 of the first chip 11 may receive 64-bit data through 64 first nodes N1 and may serialize the 64-bit data into four 16-bit data. Read data read from the cell region CELL of the first chip 11 or the cell region CELL′ of the second chip 12 may be transmitted to the first nodes N1 of the first chip 11. Then, the read data may be serialized in the serializer-deserializer 120 of the first chip 11 and output to the first pads P1a of the first chip 11 through the input/output buffers 140 of the first chip 11.

In the first chip 11, the input/output driver 130 may be connected between the first nodes N1 and the cell region CELL. The input/output driver 130 may be connected to the serializer-deserializer 120 through the first nodes N1. The input/output driver 130 may receive write data from the serializer-deserializer 120 through the first nodes N1. The input/output driver 130 may output the received write data to the cell region CELL, and accordingly, data may be stored in the cell region CELL. The input/output driver 130 may receive read data from the cell region CELL, and may output the received read data to the first nodes N1. In the second chip 12, the input/output driver 130′ may be connected between the first nodes N1′ and the cell region CELL′. The input/output driver 130′ may be connected to the serializer-deserializer 120′ through the first nodes N1′. The input/output driver 130′ may receive write data from the first chip 11 through the first connection member 21, the second pads P2a′, internal wirings L1′ and the first nodes N1′. The input/output driver 130′ may output the received write data to the cell region CELL′, and accordingly, data may be stored in the cell region CELL′. The input/output driver 130′ may receive read data from the cell region CELL′, and may output the received read data to the first nodes N1′.

In the first chip 11, the first nodes N1 may be connected to the second pads P2a through internal wirings L1. Each of the first nodes N1 may be connected to a corresponding second pad P2a through the internal wiring L1. The first nodes N1 may correspond, one-to-one, to the second pads P2a. In the second chip 12, the first nodes N1′ may be connected to the second pads P2a′ through the internal wirings L1′. Each of the first nodes N1′ may be connected to a corresponding second pad P2a′ through the internal wiring L1′. The first nodes N1′ may correspond, one-to-one, to the second pads P2a′.

The second pads P2a of the first chip 11 and the second pads P2a′ of the second chip 12 may be connected through first connection members 21. Each of the second pads P2a of the first chip 11 may be connected to a corresponding second pad P2a′ of the second chip 12 through the first connection member 21. For the sake of simplicity in illustration, in FIG. 5, illustration of first connection members 21 adjacent to the serializer-deserializer 120, among the first connection members 21, has been omitted.

The input/output driver 130 of the first chip 11 may interface with the serializer-deserializer 120 of the first chip 11 through the first nodes N1 of the first chip 11, and thereby, may exchange data with the serializer-deserializer 120 of the first chip 11.

The input/output driver 130′ of the second chip 12 may interface with the serializer-deserializer 120 of the first chip 11 through the first nodes N1′ of the second chip 12, the internal wirings L1′ of the second chip 12, the second pads P2a′ of the second chip 12, the first connection members 21, the second pads P2a of the first chip 11, the internal wirings L1 of the first chip 11 and the first nodes N1 of the first chip 11, and thereby, may exchange data with the serializer-deserializer 120 of the first chip 11.

The input/output driver 130 of the first chip 11 and the input/output driver 130′ of the second chip 12 may interface in common with the serializer-deserializer 120 of the first chip 11 and may share the serializer-deserializer 120 of the first chip 11.

The serializer-deserializer 120′ of the second chip 12 might not be used. In addition, the input/output buffers 140′ and the first pads P1a′ of the second chip 12 might not be used. The serializer-deserializer 120′, the input/output buffers 140′ and the first pads P1a′ of the second chip 12 may be dummy structures that do not function electrically. In other words, the first pads P1a′ of the second chip 12 may be dummy pads, the input/output buffers 140′ of the second chip 12 may be dummy input/output buffers, and the serializer-deserializer 120′ of the second chip 12 may be a dummy serializer-deserializer.

When a device including the semiconductor package 10 is booted, the first chip 11 may perform an initial setting operation in response to a command input from the external device. In the initial setting operation, the first chip 11 may generate a disable signal for disabling the serializer-deserializer 120′ and the input/output buffers 140′ of the second chip 12 and may provide the disable signal to the second chip 12. The serializer-deserializer 120′ and the input/output buffers 140′ of the second chip 12 may be disabled in response to the disable signal received from the first chip 11. After the initial setting operation, the serializer-deserializer 120′ and the input/output buffers 140′ of the second chip 12 may be maintained in a disabled state regardless of the operations of the semiconductor package 10 and the device including the same.

Because the serializer-deserializer 120′ and the input/output buffers 140′ of the second chip 12 are maintained in a disabled state, the power consumption of the second chip 12 may be less than that of the first chip 11. Accordingly, power consumption may be reduced compared to an example where the first chip 11 and the second chip 12 are driven in the same manner.

The first pads P1a of the first chip 11 may be connected to first top substrate pads 13A of a substrate 13 through second connection members 22. The second connection members 22 may include bonding wires. Each of the first pads P1a′ of the second chip 12 may be in floating state. Each of the first pads P1a′ of the second chip 12 might not contact a bonding wire that is connected to the substrate 13.

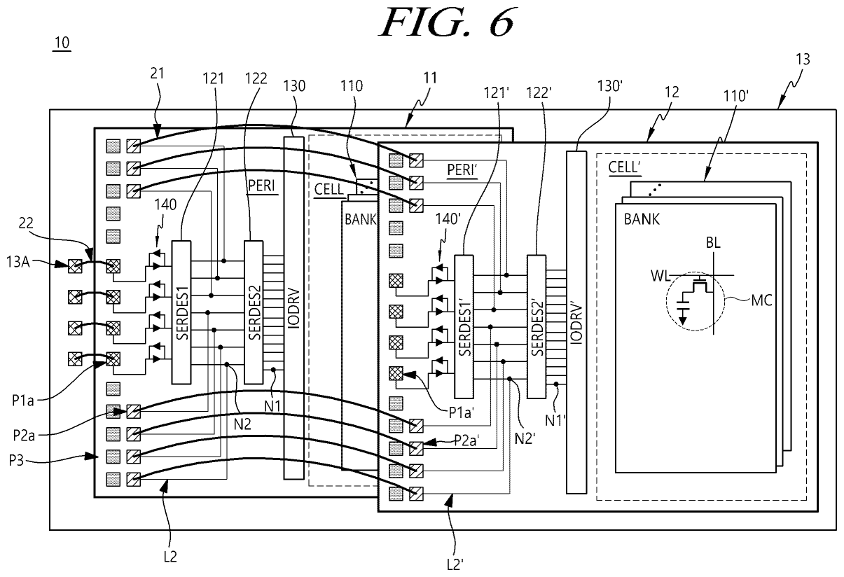

Referring to FIG. 6, a serializer-deserializer of the first chip 11 may be divided into two levels. Also, a serializer-deserializer of the second chip 12 may be divided into two levels. The serializer-deserializer of the first chip 11 may include a first level serializer-deserializer (SERDES1) 121 and a second level serializer-deserializer (SERDES2) 122. The serializer-deserializer of the second chip 12 may include a first level serializer-deserializer (SERDES1′) 121′ and a second level serializer-deserializer (SERDES2′) 122′.

In the first chip 11, the first level serializer-deserializer 121 may be connected between first pads P1a and second nodes N2. The first level serializer-deserializer 121 may be connected to the first pads P1a through input/output buffers 140. In the second chip 12, the first level serializer-deserializer 121′ may be connected between first pads P1a′ and second nodes N2′. The first level serializer-deserializer 121′ may be connected to the first pads P1a′ through input/output buffers 140′.

The first level serializer-deserializer 121 may receive write data from an external device through the first pads P1a of the first chip 11. The first level serializer-deserializer 121 may parallelize the received write data, and may output the parallelized write data to the second nodes N2 of the first chip 11.

The first level serializer-deserializer 121 may parallelize write data input through the first pads P1a, thereby expanding the window of write data to a 2F (F is a natural number) multiple.

The first level serializer-deserializer 121 may receive read data from a cell region CELL of the first chip 11 or a cell region CELL′ of the second chip 12, and may serialize the received read data. The read data may be transmitted to the second nodes N2. The read data may be serialized in the first level serializer-deserializer 121 and output to the first pads P1a through the input/output buffers 140 of the first chip 11.

In the first chip 11, the second level serializer-deserializer 122 may be connected between the second nodes N2 and first nodes N1. The second level serializer-deserializer 122 may receive write data input from the first level serializer-deserializer 121 through the second nodes N2. The second level serializer-deserializer 122 may parallelize the received write data, and may output the parallelized write data to the first nodes N1. The second level serializer-deserializer 122 may expand the window of the received write data to 2K (K is a natural number) multiple. For instance, K may be 1. In the second chip 12, the second level serializer-deserializer 122′ may be connected between the second nodes N2′ and first nodes N1′. The second level serializer-deserializer 122′ may receive write data from the first chip 11 through the first connection members 21, the internal wirings L2′, and the second nodes N2′. The second level serializer-deserializer 122′ may parallelize the received write data and may output the parallelized write data to the first nodes N1′. The second level serializer-deserializer 122′ may expand the window of the received write data to 2K (K is a natural number) multiple. For instance, K may be 1.

In the first chip 11, the second level serializer-deserializer 122 may receive read data from the cell region CELL through first nodes N1. The second level serializer-deserializer 122 may serialize the received read data, and output the serialized read data to the second nodes N2. The number of second nodes N2 may be 1/2K (K is a natural number) times the number of first nodes N1. For instance, K may be 1. When the number of first nodes N1 is 64, the number of second nodes N2 may be 32, which is half the number of first nodes N1. In the second chip 12, the second level serializer-deserializer 122′ may receive read data from the cell region CELL′ through the first nodes N1.

The second level serializer-deserializer 122′ may serialize the received read data, and output the serialized read data to the second nodes N2′. The number of second nodes N2′ may be 1/2K (K is a natural number) times the number of first nodes N1′. For instance, K may be 1. When the number of first nodes N1′ is 64, the number of second nodes N2′ may be 32, which is half the number of first nodes N1′.

In the first chip 11, the second nodes N2 may be connected to second pads P2a through internal wirings L2. The second nodes N2 and the second pads P2a may be connected to each other through the internal wirings L2. The number of second pads P2a may be the same as the number of second nodes N2. The second pads P2a may correspond, one-to-one, to the second nodes N2. In the second chip 12, the second nodes N2′ may be connected to second pads P2a′ through internal wirings L2′. The second nodes N2′ and the second pads P2a′ may be connected to each other through the internal wirings L2′. The number of second pads P2a′ may be the same as the number of second nodes N2′. The second pads P2a′ may correspond, one-to-one, to the second nodes N2′.

The second pads P2a of the first chip 11 and the second pads P2a′ of the second chip 12 may be connected to each other through first connection members 21.

The second level serializer-deserializer 122 of the first chip 11 may interface with the first level serializer-deserializer 121 of the first chip 11 through the second nodes N2 of the first chip 11 to exchange data with the first level serializer-deserializer 121 of the first chip 11.

The second level serializer-deserializer 122′ of the second chip 12 may interface with the first level serializer-deserializer 121 of the first chip 11 through the second nodes N2′ of the second chip 12, the internal wirings L2′ of the second chip 12, the second pads P2a′ of the second chip 12, the first connection members 21, the second pads P2a of the first chip 11, the internal wirings L2 of the first chip 11 and the second nodes N2 of the first chip 11 to exchange data with the first level serializer-deserializer 121 of the first chip 11.

The second level serializer-deserializer 122 of the first chip 11 and the second level serializer-deserializer 122′ of the second chip 12 may interface in common with the first level serializer-deserializer 121 of the first chip 11 and may share the first level serializer-deserializer 121 of the first chip 11.

The first level serializer-deserializer 121′ of the second chip 12 might not be used. In addition, the input/output buffers 140′ of the second chip 12 and the first pads P1a′ of the second chip 12 might not be used. The first level serializer-deserializer 121′, the input/output buffers 140′ and the first pads P1a′ of the second chip 12 may be non-functional dummy structures. Namely, the first pads P1a′ of the second chip 12 may be dummy pads, the input/output buffers 140′ of the second chip 12 may be dummy input/output buffers, and the first level serializer-deserializer 121′ of the second chip 12 may be a dummy first level serializer-deserializer.

When a device including the semiconductor package 10 is booted, the first chip 11 may perform an initial setting operation in response to an external command input from the external device. In the initial setting operation, the first chip 11 may generate a disable signal for disabling the first level serializer-deserializer 121′ and the input/output buffers 140′ of the second chip 12 and may provide the disable signal to the second chip 12. The first level serializer-deserializer 121′ and the input/output buffers 140′ of the second chip 12 may be disabled in response to the disable signal from the first chip 11. After the initial setting operation, the first level serializer-deserializer 121′ and the input/output buffers 140′ of the second chip 12 may be maintained in a disabled state regardless of the operations of the semiconductor package 10 and the device including the same.

Because the first level serializer-deserializer 121′ and the input/output buffers 140′ of the second chip 12 are maintained in a disabled state, the power consumption of the second chip 12 may be less than that of the first chip 11. Accordingly, power consumption may be reduced compared to the example of driving the first chip 11 and the second chip 12 in the same manner.

According to the present embodiment, because the serializer-deserializer of the first chip 11 is divided into the first level serializer-deserializer 121 and the second level serializer-deserializer 122 and the second pads P2a are connected to the second nodes N2 between the first level serializer-deserializer 121 and the second level serializer-deserializer 122, the number of second pads P2a may be reduced when compared to an example in which the second pads P2a are connected to the first nodes N1. Because the serializer-deserializer of the second chip 12 is divided into the first level serializer-deserializer 121′ and the second level serializer-deserializer 122′ and the second pads P2a′ are connected to the second nodes N2′ between the first level serializer-deserializer 121′ and the second level serializer-deserializer 122′, the number of second pads P2a′ may be reduced when compared to an example in which the second pads P2a′ are connected to the first nodes N1′. Accordingly, the number of first connection members 21 connecting the second pads P2a of the first chip 11 and the second pads P2a′ of the second chip 12 may be reduced, and the space required to dispose the first connection members 21 may be reduced.

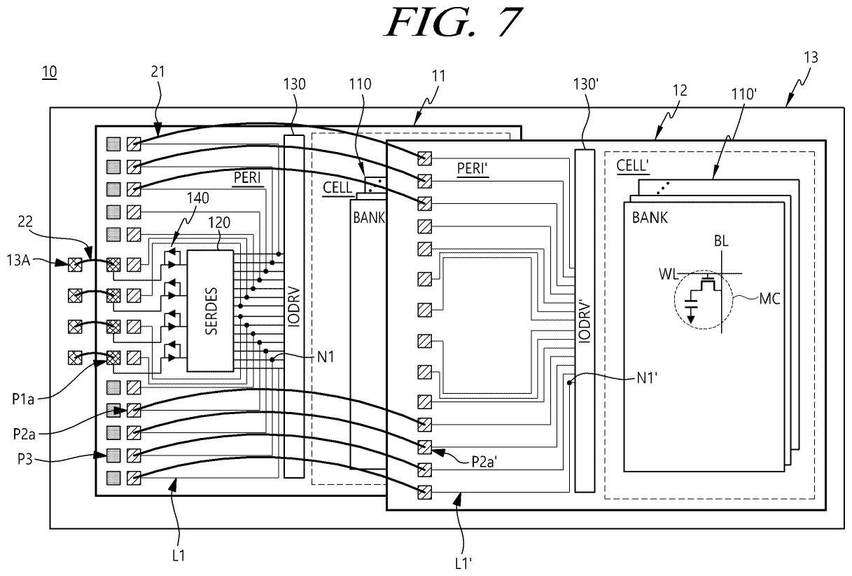

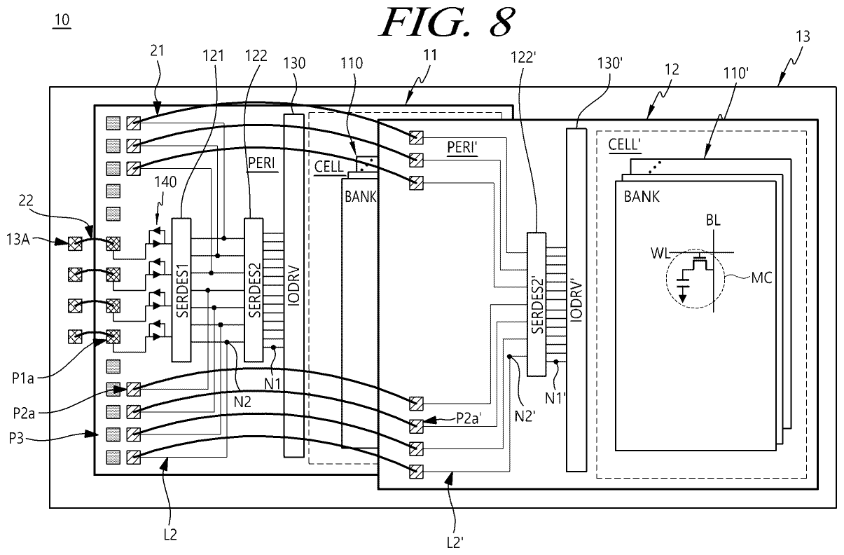

Although an example in which the first chip 11 and the second chip 12 are the same type of chips has been described, the first chip 11 and the second chip 12 may be different types of chips. In this example, as described below with reference to FIG. 7 and FIG. 8, the configuration disabled in the second chip 12 in the previous embodiment may be optional.

Referring to FIG. 7, compared to the second chip 12 of FIG. 5, a second chip 12 might not include a serializer-deserializer 120′ of FIG. 5, input/output buffers 140′ of FIG. 5 and first pads P1a′ of FIG. 5. The second chip 12 might also not include other external signal pads.

Although FIG. 7 illustrates an example in which the second chip 12 does not include all of the serializer-deserializer 120′, the input/output buffers 140′ and the first pads P1a′, the second chip 12 might not include at least one of the serializer-deserializer 120′, the input/output buffers 140′, and the first pads P1a′. Although not shown, the second chip 12 mighty also not include other external signal pads, for example, an external command/address (CA) pad and an external clock pad.

As at least one of the serializer-deserializer 120′, the input/output buffers 140′, the external signal pads and power pads P3′ has been omitted, space for an omitted component could be saved. Thus, the second chip 12 may be smaller in size than the first chip 11.

Referring to FIG. 8, compared to the second chip 12 of FIG. 6, a second chip 12 might not include a first level serializer-deserializer 121′ of FIG. 6, input/output buffers 140′ of FIG. 6, and first pads P1a′ of FIG. 6.

Although FIG. 8 illustrates an example in which the second chip 12 does not include all of the first level serializer-deserializer 121′, the input/output buffers 140′, and the first pads P1a′, the second chip 12 might not include at least one of the first level serializer-deserializer 121′, the input/output buffers 140′, and the first pads P1a′. Although not shown, the second chip 12 might also not include other external signal pads.

As at least one of the first level serializer-deserializer 121′, the input/output buffers 140′, the external signal pads, and power pads P3′ has been omitted, space for an omitted component could be saved. Thus, the second chip 12 may be smaller in size than the first chip 11.

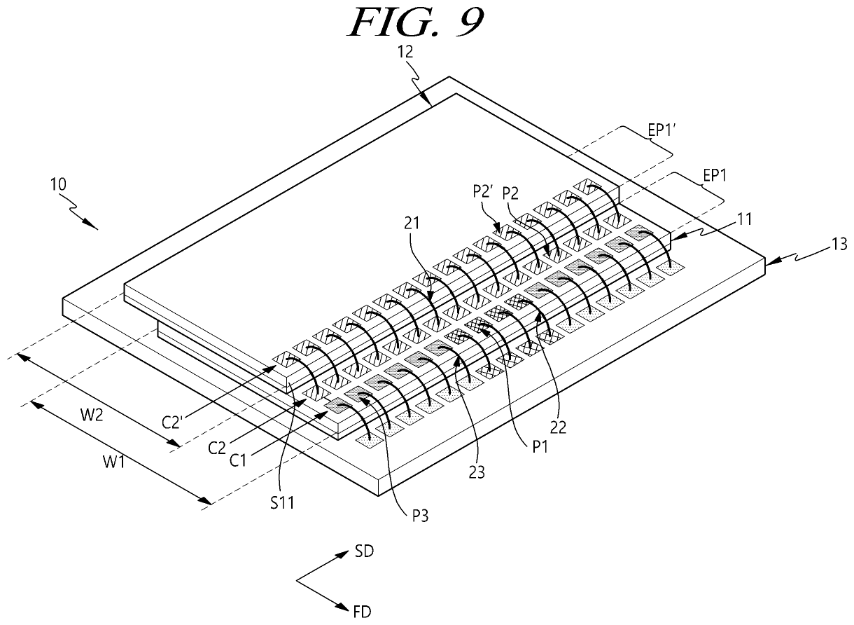

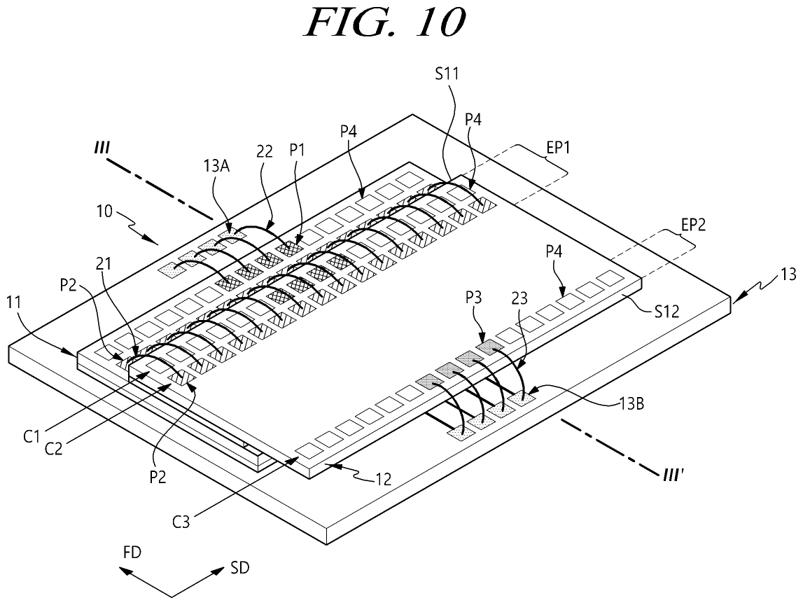

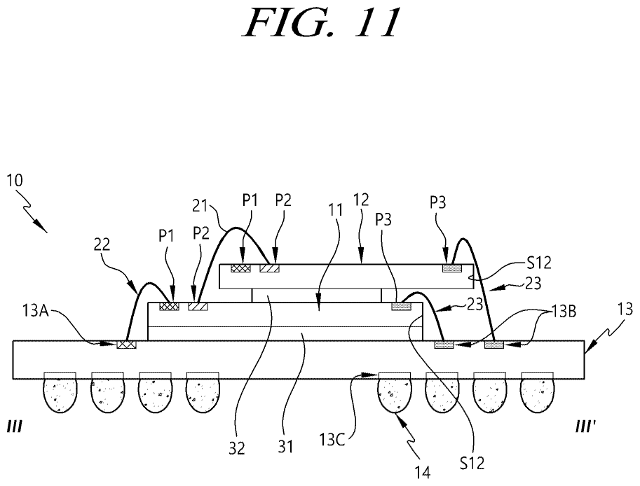

FIG. 9 is a perspective view of a semiconductor package based on an embodiment of the disclosed technology, illustrating an example where a first chip 11 and a second chip 12 are different types of chips.

Referring to FIG. 9, compared to the first chip 11, the second chip 12 might not include external signal pads P1.

As the second chip 12 does not include external signal pads P1, the second chip 12 might not have a pad column for disposing external signal pads P1. The second chip 12 may have less pad columns than the first chip 11.

Because the second chip 12 includes less pad columns than the first chip 11, the second chip 12 may have a smaller width than the first chip 11. For instance, when the width of the first chip 11 is W1, the width of the second chip 12 may be W2, which is smaller than W1.

As the second chip 12 does not have a pad column for disposing external signal pads P1, a pad column C2′ in which slice signal pads P2′ are disposed in the second chip 12 may be disposed close to a first side surface S11 of the second chip 12, which is adjacent to a first edge portion EP1 of the first chip 11.

The slice signal pads P2 of the first chip 11 and the slice signal pads P2′ of the second chip 12, which are connected to each other through first connection members 21, may be adjacent to each other with the first side surface S11 of the second chip 12 interposed therebetween. The first connection members 21 may have a short length that connects the slice signal pads P2 of the first chip 11 to the slice signal pads P2′ of the second chip 12, which are adjacent to each other.

Although the embodiments of FIG. 2 to FIG. 9 illustrate an example in which the power pads P3 are disposed in the first edge portion EP1 or EP1′ together with the external signal pads P1 and the slice signal pads P2 or P2′, the power pads P3 may be disposed in another edge portion of a chip other than the first edge portion EP1 or EP1′, as will be described below with reference to FIG. 10 to FIG. 13.

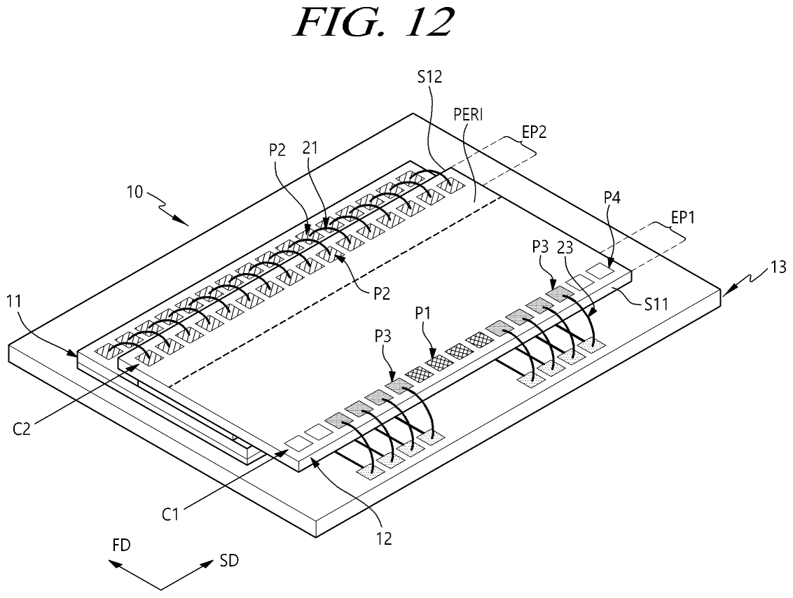

FIG. 10 is a perspective view of a semiconductor package based on an embodiment of the disclosed technology, and FIG. 11 is a cross-sectional view taken along the line III-III′ of FIG. 10.

Referring to FIG. 10 and FIG. 11, each of first and second chips 11 and 12 may include a third pad column C3 that is located in a second edge portion EP2 on the opposite side of the corresponding chip compared to a first edge portion EP1. For example, the third pad column C3 may be an outermost pad column that is closest to a second side surface S12 included in the second edge portion EP2, among a plurality of pad columns included in each chip. In each of the first and second chips 11 and 12, power pads P3 may be included in the third pad column C3. Pads P4 for another purpose not described may be additionally disposed in at least one of first and third pad columns C1 and C3. For the sake of simplicity in illustration, FIG. 10 illustrates that connection members are not connected to the pads P4, but, if necessary, connection members may be connected to the pads P4.

The power pads P3 of the first chip 11 and the power pads P3 of the second chip 12 may be connected to second top substrate pads 13B of a substrate 13 through third connection members 23. When viewed from the top, the second top substrate pads 13B that are connected to the power pads P3 of the first chip 11 through the third connection members 23 may be adjacent to the second edge portion EP2 of the first chip 11. When viewed from the top, the second top substrate pads 13B that are connected to the power pads P3 of the second chip 12 through the third connection members 23 may be adjacent to the second edge portion EP2 of the second chip 12. The third connection members 23 may be disposed on the side of the second edge portions EP2 of the first and second chips 11 and 12.

By disposing the power pads P3 in the second edge portion EP2, an area allocated to dispose slice signal pads P2 in the first edge portion EP1 may be increased. For example, the number of slice signal pads P2 disposed in the first edge portion EP1 may be increased. Also, power supply capability may be improved by increasing the size of the slice signal pads P2.

FIG. 10 and FIG. 11 illustrate an example in which the first chip 11 and the second chip 12 are the same type of chips and the second chip 12 includes external signal pads P1 that are not used, although the disclosed technology is not limited thereto. Although not shown, the first chip 11 and the second chip 12 may be different types of chips, and the second chip 12 might not include external signal pads P1 compared to the first chip 11.

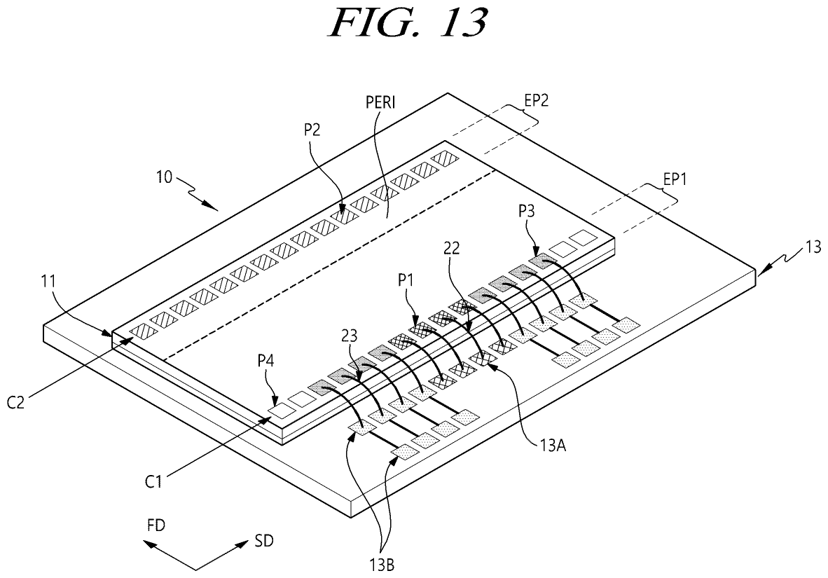

FIG. 12 is a perspective view of a semiconductor package based on an embodiment of the disclosed technology, and FIG. 13 is a perspective view illustrating a substrate, a first chip, and connection members connecting the substrate to the first chip in FIG. 12.

Referring to FIG. 12 and FIG. 13, in each of first and second chips 11 and 12, a first pad column C1 may be located in a first edge portion EP1, and a second pad column C2 may be located in a second edge portion EP2. Among a plurality of pad columns included in each chip, the first pad column C1 may be an outermost pad column that is closest to a first side surface S11 of each chip, and the second pad column C2 may be an outermost pad column that is closest to a second side surface S12 of each chip.

In each of the first and second chips 11 and 12, external signal pads P1 and power pads P3 may be included in the first pad column C1, and slice signal pads P2 may be included in the second pad column C2.

The second chip 12 may be offset with respect to the first chip 11 and exposes or facilitates access to the second pad column C2 including the slice signal pads P2 of the first chip 11. Because the second pad column C2 of the first chip 11 is an outermost pad column, the second chip 12 may be offset with respect to the first chip 11 by only a distance corresponding to one pad column.

Each of the first and second chips 11 and 12 may have a peripheral region PERI including the second edge portion EP2. Although not shown, a peripheral circuit (not shown) that is connected to the slice signal pads P2 may be disposed in the peripheral region PERI. For example, the peripheral circuit may include the serializer-deserializer 120, the input/output driver 130 and the input/output buffers 140 of FIG. 5. For another example, the peripheral circuit may include the first and second level serializer-deserializers 121 and 122, the input/output driver 130 and the input/output buffers 140 of FIG. 6. The slice signal pads P2 and the peripheral circuit may be disposed close to each other in the peripheral region PERI.

By disposing the external signal pads P1 and the power pads P3 in the first edge portion EP1, the second edge portion EP2 may be fully allocated for the disposition of the slice signal pads P2. Accordingly, because the number of slice signal pads P2 disposed in the second edge portion EP2 may be increased, even when the number of slice signals is large, the slice signals may be transmitted using first connection members 21.

FIG. 14 is a perspective view of a semiconductor package based on an embodiment of the disclosed technology.

Referring to FIG. 14, each of first and second chips 11 and 12 may include a first pad column C1 that is located in a first edge portion EP1 and a second pad column C2 that is located in a second edge portion EP2.

In each of the first and second chips 11 and 12, external signal pads P1 and slice signal pads P2 may be included in the first pad column C1.

Each of the first and second chips 11 and 12 may have a peripheral region PERI including the first edge portion EP1. A peripheral circuit (not shown) that is connected to the external signal pads P1 and the slice signal pads P2 may be disposed in the peripheral region PERI. For example, the peripheral circuit may include the serializer-deserializer 120, the input/output driver 130 and the input/output buffers 140 of FIG. 5. For another example, the peripheral circuit may include the first and second level serializer-deserializers 121 and 122, the input/output driver 130 and the input/output buffers 140 of FIG. 6.

The slice signal pads P2 of the first chip 11 and the slice signal pads P2 of the second chip 12 may be connected to each other through first connection members 21. The first connection members 21 may be disposed on the side of the first edge portions EP1 of the first and second chips 11 and 12.

The external signal pads P1 of the first chip 11 and first top substrate pads 13A of a substrate 13 may be connected through second connection members 22. The second connection members 22 may be disposed on the side of the first edge portion EP1 of the first chip 11.

Power pads P3 of the first and second chips 11 and 12 may be connected to second top substrate pads 13B of the substrate 13 through third connection members 23. The third connection members 23 may be disposed on the side of the second edge portions EP2 of the first and second chips 11 and 12.

FIG. 12 and FIG. 14 illustrate an example in which the first chip 11 and the second chip 12 are the same type of chips and the second chip 12 includes external signal pads P1 that are not used, although the disclosed technology is not limited thereto. Although not shown, the first chip 11 and the second chip 12 may be different types of chips, and the second chip 12 might not include external signal pads P1 compared to the first chip 11.

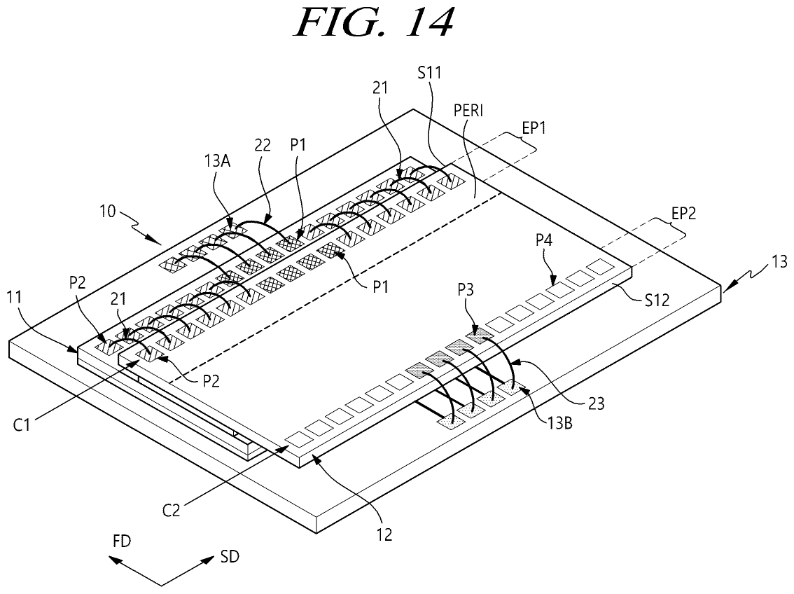

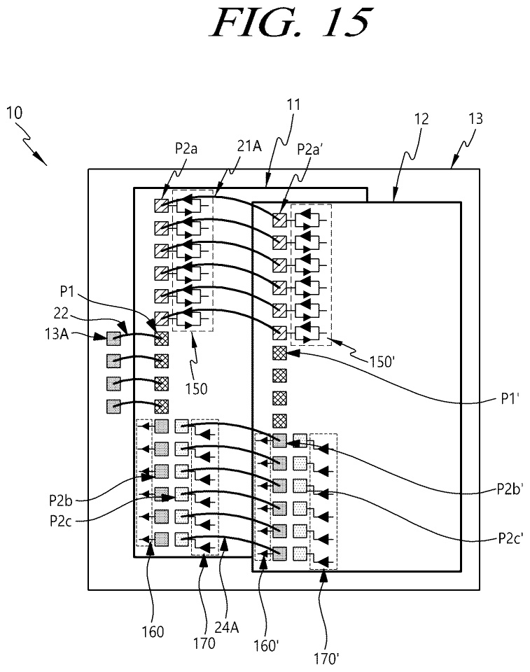

FIG. 15 is a view illustrating a semiconductor package based on an embodiment of the disclosed technology.

Referring to FIG. 15, a semiconductor package 10 includes a substrate 13, a first chip 11 and a second chip 12.

The first chip 11 is a master chip, and the second chip 12 is a slave chip.

The first chip 11 includes external signal pads P1 and slice signal pads P2a, P2b and P2c.

The external signal pads P1 include external data pads, external command/address pads, and external clock pads. The slice signal pads P2a, P2b and P2c include slice data pads P2a, slice command/address reception pads P2b, and slice command/address transmission pads P2c. For example, the external pads transmit signals to or receive signals from an element outside the semiconductor package 10, such as the controller 20.

The first chip 11 receives write data through external data pads from an external device, such as the controller 20. The first chip 11 may parallelize the received write data.

The first chip 11 receives an external command and an external address through the external signal pads P1 from the external device. The first chip 11 generates a slice command by decoding the received external command. The first chip 11 generates a slice address by decoding the received external address.

The first chip 11 includes a plurality of second input/output buffers 150, a plurality of input buffers 160, and a plurality of output buffers 170. Although not illustrated in FIG. 15, as described with reference to FIG. 5, the first chip 11 includes a cell region, a serializer-deserializer, an input/output driver, and a plurality of first input/output buffers. In another example, as described with reference to FIG. 6, the first chip 11 may include a cell region, first and second serializer-deserializers, an input/output driver, and a plurality of first input/output buffers.

Each of the second input/output buffers 150 are connected to a corresponding slice data pad P2a. The second input/output buffers 150 correspond on a one-to-one basis to the slice data pads P2a.

For example, each of the second input/output buffers 150 is connected between the slice data pads P2a and the first nodes N1 of FIG. 5. In this example, the second input/output buffers 150 receive parallelized write data from the serializer-deserializer 120 of FIG. 5 of the first chip 11 and outputs the received write data to the second chip 12 through the slice data pads P2a. The second input/output buffers 150 receives read data through the slice data pads P2a from the second chip 12 and outputs the received read data to the serializer-deserializer 120 of FIG. 5 of the first chip 11.

In another example, each of the second input/output buffers 150 are connected between the slice data pad P2a and the second node N2 of FIG. 6. In this example, the second input/output buffers 150 receive parallelized write data from the first serializer-deserializer (121 of FIG. 6) of the first chip 11 and outputs the received write data to the second chip 12 through the slice data pads P2a. The second input/output buffers 150 receive read data through the slice data pads P2a from the second chip 12 and outputs the received read data to the first serializer-deserializer 121 of FIG. 6 of the first chip 11.

Each of the input buffers 160 is connected to a corresponding slice command/address reception pad P2b. The input buffers 160 corresponds on a one-to-one basis to the slice command/address reception pads P2b.

The input buffers 160 might not be used. The slice command/address reception pads P2b might not be used. The input buffers 160 and the slice command/address reception pads P2b may be a dummy structure that does not function electrically. The input buffers 160 may be dummy input buffers, and the slice command/address reception pads P2b may be dummy pads.

Each of the output buffers 170 are connected to a corresponding slice command/address transmission pad P2c. The output buffers 170 correspond on a one-to-one basis to the slice command/address transmission pads P2c.

The output buffers 170 buffer slice commands/addresses and output the buffered slice commands/addresses to the slice command/address transmission pads P2c. The output terminal of the output buffer 170 is not connected to the input terminal of the input buffer 160. The second chip 12 may have physically the same structure as the first chip 11. The second chip 12 may be the same type of chip as the first chip 11. The second chip 12 may be the same size, for example, in height, length, and/or width, as the first chip 11.

The second chip 12 includes external signal pads P1′ and slice signal pads P2a′, P2b′ and P2c′.

The external signal pads P1′ include external data pads, external command/address pads, and external clock pads. The slice signal pads P2a′, P2b′ and P2c′ include slice data pads P2a′, slice command/address reception pads P2b′, and slice command/address transmission pads P2c′.

Each of the slice data pads P2a′ of the second chip 12 is connected to a corresponding slice data pad P2a of the first chip 11 through a first connection member 21A. First connection members 21A may include bonding wires.

Each of the slice command/address reception pads P2b′ of the second chip 12 is connected to a corresponding slice command/address transmission pad P2c of the first chip 11 through a fourth connection member 24A. Fourth connection members 24A may include bonding wires.

The second chip 12 includes a plurality of second input/output buffers 150′, a plurality of input buffers 160′, and a plurality of output buffers 170′. Although not illustrated in FIG. 15, as described with reference to FIG. 5, the second chip 12 includes a cell region, a serializer-deserializer, an input/output driver, and a plurality of first input/output buffers. In another example, as described with reference to FIG. 6, the second chip 12 includes a cell region, first and second serializer-deserializers, an input/output driver, and a plurality of first input/output buffers.

Each of the second input/output buffers 150′ are connected to a corresponding slice data pad P2a′. The second input/output buffers 150′ correspond on a one-to-one basis to the slice data pads P2a′.

For example, each of the second input/output buffers 150′ are connected between the slice data pad P2a′ and the first nodes N1′ of FIG. 5. In this example, the second input/output buffers 150′ receive parallelized write data from the first chip 11 through the first connection members 21A and the slice data pads P2a′ and output the received write data to the first nodes N1′ of FIG. 5 and the input/output driver 130′ of FIG. 5. The second input/output buffers 150′ receive read data read from the cell region CELL′ of FIG. 5 of the second chip 12 through the input/output driver 130′ of FIG. 5 and the first nodes N1′ of FIG. 5 and output the received read data to the first chip 11 through the slice data pads P2a′ and the first connection members 21A.

In another example, each of the second input/output buffers 150′ is connected between the slice data pad P2a′ and the second nodes N2′ of FIG. 6. In this example, the second input/output buffers 150′ receive parallelized write data from the first chip 11 through the slice data pads P2a′ and the first connection members 21A and output the received write data to the second level serializer-deserializer 122′ of FIG. 6 through the second nodes N2′ of FIG. 6. The second input/output buffers 150′ receive read data read from the cell region CELL′ of FIG. 6 of the second chip 12 through the second level serializer-deserializer 122′ of FIG. 6, the input/output driver (130′ of FIG. 6), and the second nodes (N2′ of FIG. 6) and output the received read data to the first chip 11 through the slice data pads P2a′ and the first connection members 21A.

Each of the input buffers 160′ is connected to a corresponding slice command/address reception pad P2b′. The input terminal of each input buffer 160′ is connected to a corresponding slice command/address reception pad P2b′. The input buffers 160′ correspond on a one-to-one basis to the slice command/address reception pads P2b′.

The input buffers 160′ receive slice commands/addresses from the first chip 11 through the slice command/address reception pads P2b′ and the fourth connection members 24A.

Each of the output buffers 170′ may be connected to a corresponding slice command/address transmission pad P2c′. The output terminal of each output buffer 170′ may be connected to a corresponding slice command/address transmission pad P2c′. The output buffers 170′ may correspond on a one-to-one basis to the slice command/address transmission pads P2c′. The output terminal of the output buffer 170′ is not connected to the input terminal of the input buffer 160′. The output terminal of the output buffer 170′ and the input terminal of the input buffer 160′ do not share a node.

The output buffers 170′ might not be used. The slice command/address transmission pads P2c′ might not be used. The output buffers 170′ and the slice command/address transmission pads P2c′ may be dummy structures that do not function electrically. The output buffers 170′ may be dummy output buffers, and the slice command/address transmission pads P2c′ may be dummy pads.

When a device including the semiconductor package 10 is booted, the first chip 11 perform an initial setting operation in response to a command inputted from the external device. During the initial setting operation, the first chip 11 generates a disable signal for disabling the input buffers 160 of the first chip 11 and the output buffers 170′ of the second chip 12. In response to the disable signal, the input buffers 160 of the first chip 11 and the output buffers 170′ of the second chip 12 are disabled. After the initial setting operation, the input buffers 160 of the first chip 11 and the output buffers 170′ of the second chip 12 are maintained in the disabled state regardless of the operations of the semiconductor package 10 and the device including the semiconductor package 10.

Because the input buffers 160 of the first chip 11 and the output buffers 170′ of the second chip 12 are maintained in the disabled state, power consumption is reduced compared to an example when the input buffers 160 of the first chip 11 and the output buffers 170′ of the second chip 12 are enabled.

Each of the output buffers 170 of the first chip 11 are connected to the input buffer 160′ of the second chip 12 through the slice command/address transmission pad P2c, the fourth connection member 24A, and the slice command/address reception pad P2b′. Each of the output buffers 170 of the first chip 11 interfaces with the input buffer 160′ of the second chip 12 through the slice command/address transmission pad P2c, the fourth connection member 24A, and the slice command/address reception pad P2b′. In an embodiment, the input buffer 160′ of the second chip 12 is connected to the output buffer 170 of the first chip 11, and the output buffer 170′ of the second chip 12 is not connected to the output buffer 170 of the first chip 11. The output buffer 170 of the first chip 11 is coupled with the input buffer 160′ of the second chip 12, and is load-decoupled from the output buffer 170′ of the second chip 12.

Because the output buffer 170 of the first chip 11 is load-decoupled from the output buffer 170′ of the second chip 12, the loading factor of the output buffer 170 of the first chip 11 is reduced compared to when the output buffer 170 of the first chip 11 is coupled with the output buffer 170′ of the second chip 12.

In the first and second chips 11 and 12, the size of the output buffers 170 and 170′ may be larger than the size of the input buffers 160 and 160′.

In order to establish or achieve sufficient signal integrity SI for a slice command/address, the output buffers 170 of the first chip 11 are configured to have a relatively larger size compared to the size of the input buffers 160, and in order to reduce the load of the output buffers 170 of the first chip 11, the input buffers 160′ of the second chip 12 are configured to have a relatively smaller size compared to the size of the output buffers 170′. Because the first chip 11 and the second chip 12 are the same type of chips, the output buffers 170′ of the second chip 12 are configured to have a relatively larger size compared to the size of the input buffers 160′, and the input buffers 160 of the first chip 11 are configured to have a relatively smaller size compared to the size of the output buffers 170.

Because write data is parallelized in the first chip 11 and is subsequently transmitted to the second chip 12 through the second input/output buffers 150, and slice commands/addresses are transmitted to the second chip 12 through the output buffers 170 without a parallelization process, the slice commands/addresses transmitted from the first chip 11 to the second chip 12 advantageously has a higher bit rate compared to the write data transmitted from the first chip 11 to the second chip 12. The slice commands/addresses are transmitted at higher speed than the transmission speed of the write data.

Due to the faster transmission speed, the slice commands/addresses may have poor signal integrity (SI). In order to establish sufficient signal integrity for the slice commands/addresses, the size of the output buffers 170 of the first chip 11 may be increased to increase drive strength.

Unlike the disclosed technology in which the output buffer 170 of the first chip 11 is load-decoupled from the output buffer 170′ of the second chip 12, in an example where the output buffer of a first chip is coupled with the output buffer of a second chip, the output buffer of the first chip receives the load of the output buffer of the second chip and thus is encumbered by the load of the output buffer of the second chip. When the size of the output buffer of the first chip is increased to establish sufficient signal integrity of slice commands/addresses, the size of the output buffer of the second chip that is the same type as the first chip also increases, and as the size of the output buffer of the second chip increases, the load (capacitance) of the output buffer of the first chip increases. In order to drive the increased load, the size of the output buffer of the first chip should be further increased, which causes a further increase in load. When the size of the output buffer of the first chip is increased to establish or achieve sufficient signal integrity, the load of the output buffer of the first chip increases, and the size of the output buffer of the first chip should be further increased. Accordingly, the load of the output buffer of the first chip further increases. Because the output buffer of the first chip has a very large size and a very large load, an increase in power consumption due to an increase in the size of the output buffer of the first chip as well as an increase in power consumption due to an increase in the load of the output buffer of the first chip results in increased power consumption. When the output buffer of the first chip is configured with a smaller size to reduce power consumption, signal integrity might not be sufficient, resulting in difficulties in transmitting slice commands/addresses at high speed.

According to the embodiment of the disclosed technology, because the output buffer 170 of the first chip 11 is load-decoupled from the output buffer 170′ of the second chip 12, the size of the output buffer 170 may be increased without an increase in the load of the output buffer 170, and the signal integrity of slice commands/addresses may be sufficient to transmit the slice commands/addresses at high speed.

According to the embodiment of the disclosed technology, because the output buffer 170 of the first chip 11 is load-decoupled from the output buffer 170′ of the second chip 12, compared to an example where the output buffer 170 of the first chip 11 is coupled with the output buffer 170′ of the second chip 12, the load of the output buffer 170 of the first chip 11 may be smaller, and the size of the output buffer 170 may be decreased to reduce power consumption.

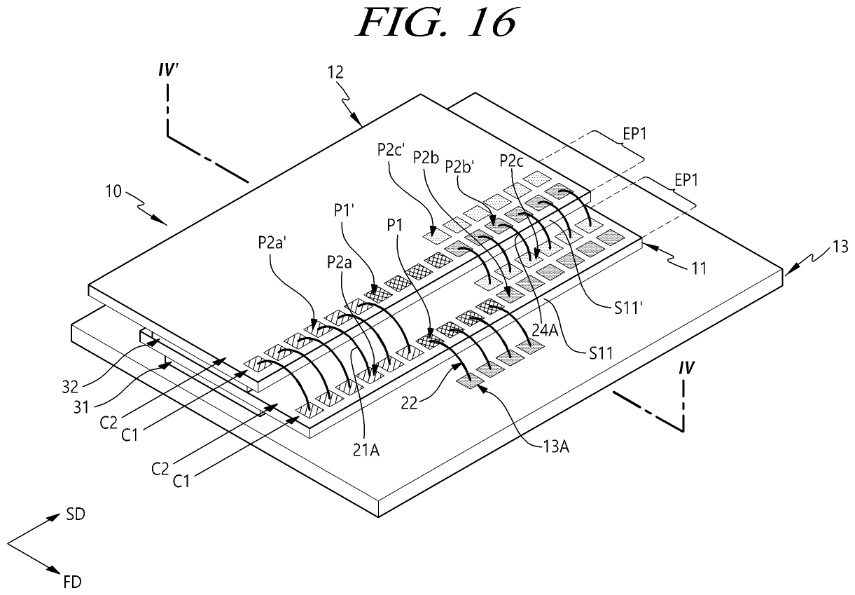

FIG. 16 is a perspective view illustrating an example of the semiconductor package, for example, as shown in FIG. 15, and FIG. 17 is a cross-sectional view taken along the line IV-IV′ of FIG. 16.

Referring to FIG. 16 and FIG. 17, the first chip 11 is disposed on the substrate 13, and the second chip 12 is disposed on the first chip 11. A first adhesive layer 31 is disposed between the substrate 13 and the first chip 11 to attach the first chip 11 and the substrate 13. A second adhesive layer 32 is disposed between the first chip 11 and the second chip 12 to attach the first chip 11 and the second chip 12.

Each of the first chip 11 and the second chip 12 includes a first pad column C1 and a second pad column C2 that are located in a first edge section or portion EP1.

For example, the first pad column C1 among a plurality of pad columns of the first chip 11 is an outermost pad column that is closest to a first side surface S11 of the first chip 11 and is included in the first edge portion EP1. The second pad column C2 among the plurality of pad columns of the first chip 11 is a pad column that is closest to the first side surface S11′ of the second chip 12 and is next to the first pad column C1 of the first chip 11. The first pad column C1 among a plurality of pad columns of the second chip 12 is an outermost pad column that is closest to a first side surface S11′ of the second chip 12 and is included in the first edge portion EP1 of the second chip 12. The second pad column C2 among the plurality of pad columns of the second chip 12 is a pad column that is next to the first pad column C1 of the second chip 12.

The external signal pads P1, the slice data pads P2a and the slice command/address reception pads P2b are included in the first pad column C1 of the first chip 11, and the slice command/address transmission pads P2c are included in the second pad column C2 of the first chip 11.

The external signal pads P1′, the slice data pads P2a′ and the slice command/address reception pads P2b′ are included in the first pad column C1 of the second chip 12, and the slice command/address transmission pads P2c′ are included in the second pad column C2 of the second chip 12.

The second chip 12 is offset with respect to the first chip 11 in the first direction FD and exposes or facilitates access to the first pad column C1 and the second pad column C2 of the first chip 11. The second chip 12 is offset with respect to the first chip 11 by a distance corresponding to at least two pad columns.

Each of the slice data pads P2a that are included in the first pad column C1 of the first chip 11 is connected to a different one of the slice data pads P2a′ that are included in the first pad column C1 of the second chip 12 by one of the first connection members 21A. Each of the first connection members 21A connects the slice data pad P2a and the nearest or nearby slice data pad P2a′, where the second pad column C2 of the first chip 11 and the first side surface S11′ of the second chip 12 are interposed between the slice data pad P2a and the slice data pad P2a′.

Each of the slice command/address transmission pads P2c that are included in the second pad column C2 of the first chip 11 is connected to a different one of the slice command/address reception pads P2b′ that are included in the first pad column C1 of the second chip 12 by one of the fourth connection members 24A. Each of the fourth connection members 24A connect the slice command/address transmission pad P2c and the nearest or nearby slice command/address reception pad P2b′, where the first side surface S11′ of the second chip 12 is interposed between the slice command/address transmission pad P2c and the slice command/address reception pad P2b′.

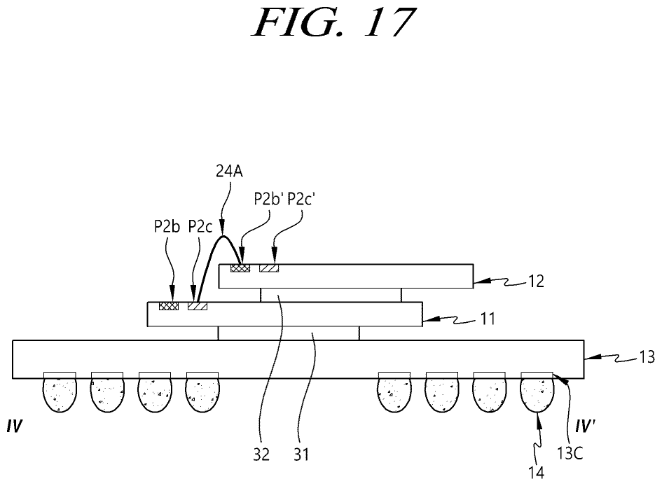

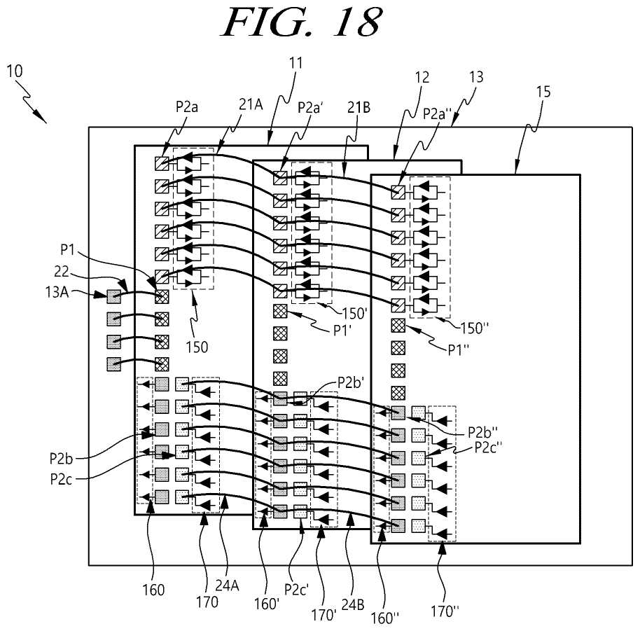

FIG. 18 is a view illustrating a semiconductor package based on an embodiment of the disclosed technology.

Referring to FIG. 18, compared to the semiconductor package 10 of FIG. 15, a semiconductor package 10 of FIG. 18 includes a third chip 15, fifth connection members 21B, and sixth connection members 24B. The descriptions of components of FIG. 18 the same as components of FIG. 15 are described with respect to FIG. 15.

The first chip 11 is a master chip, and the second chip 12 and the third chip 15 are slave chips.

The third chip 15 may have physically the same structure as each of the first chip 11 and the second chip 12. The third chip 15 may be the same type of chip as the first chip 11 and the second chip 12. The third chip 15 may be the same size as each of the first chip 11 and the second chip 12.

The third chip 15 includes external signal pads P1″ and slice signal pads P2a″, P2b″, and P2c″.

The external signal pads P1″ include external data pads, external command/address pads, and external clock pads. The slice signal pads P2a″, P2b″ and P2c″ include slice data pads P2a″, slice command/address reception pads P2b″, and slice command/address transmission pads P2c″.

The third chip 15 includes a plurality of second input/output buffers 150″, a plurality of input buffers 160″, and a plurality of output buffers 170″. Although not illustrated in FIG. 18, the third chip 15 includes a cell region, a serializer-deserializer, an input/output driver, and a plurality of first input/output buffers. In another example, the third chip 15 includes a cell region, first and second serializer-deserializers, an input/output driver, and a plurality of first input/output buffers.

Each of the second input/output buffers 150″ is connected to a corresponding slice data pad P2a″. The second input/output buffers 150″ corresponds on a one-to-one basis to the slice data pads P2a″.

Each of the second input/output buffers 150″ is connected to the first chip 11 through the first connection member 21A, the fifth connection member 21B, and the slice data pad P2a″. The connection members 21A and 21B may include bonding wires.

The second input/output buffers 150″ receive write data from the first chip 11 through the first connection members 21A, the fifth connection members 21B, and the slice data pads P2a″. The write data received through the second input/output buffers 150″ is stored in the cell region (not illustrated) of the third chip 15.

The second input/output buffers 150″ receives read data read from the cell region (not illustrated) of the third chip 15 and outputs the received read data to the first chip 11 through the slice data pads P2a″, the fifth connection members 21B, and the first connection members 21A.

Each of the input buffers 160″ is connected to a corresponding slice command/address reception pad P2b″. The input buffers 160″ correspond on a one-to-one basis to the slice command/address reception pads P2b″.

Each of the input buffers 160″ is connected to the first chip 11 through the fourth connection members 24A, the sixth connection members 24B, and the slice command/address reception pads P2b″. The connection members 24A and 24B may include bonding wires.

The input buffers 160″ receive slice commands/addresses from the first chip 11 through the fourth connection members 24A, the sixth connection members 24B, and the slice command/address reception pads P2b″.

Each of the output buffers 170″ is connected to a corresponding slice command/address transmission pad P2c″. The output buffers 170″ corresponds on a one-to-one basis to the slice command/address transmission pads P2c″.

The output buffers 170″ might not be used. The slice command/address transmission pads P2c″ might not be used. The output buffers 170″ and the slice command/address transmission pads P2c″ may be a dummy structure that does not function electrically. The output buffers 170″ may be dummy output buffers, and the slice command/address transmission pads P2c″ may be dummy pads.

The output buffer 170″ of the third chip 15 may be a larger than the input buffer 160″.

Each of the output buffers 170 of the first chip 11 is connected to the input buffer 160″ of the third chip 15 through the slice command/address transmission pad P2c, the fourth connection member 24A, the sixth connection member 24B, and the slice command/address reception pad P2b″. Each of the output buffers 170 of the first chip 11 interfaces with the input buffer 160″ of the third chip 15 through the slice command/address transmission pad P2c, the fourth connection member 24A, the sixth connection member 24B, and the slice command/address reception pad P2b″.

Optionally, only the input buffer 160″ of the third chip 15 is connected to the output buffer 170 of the first chip 11, and the output buffer 170″ of the third chip 15 might not be connected to the output buffer 170 of the first chip 11. Each of the output buffers 170 of the first chip 11 is coupled with the input buffer 160″ of the third chip 15 and is load-decoupled from the output buffer 170″ of the third chip 15. Because the output buffer 170 of the first chip 11 is load-decoupled from the output buffer 170″ of the third chip 15, the loading factor of the output buffers 170 of the first chip 11 is reduced compared to an example where the output buffer 170 of the first chip 11 is coupled with the output buffer 170″ of the third chip 15.

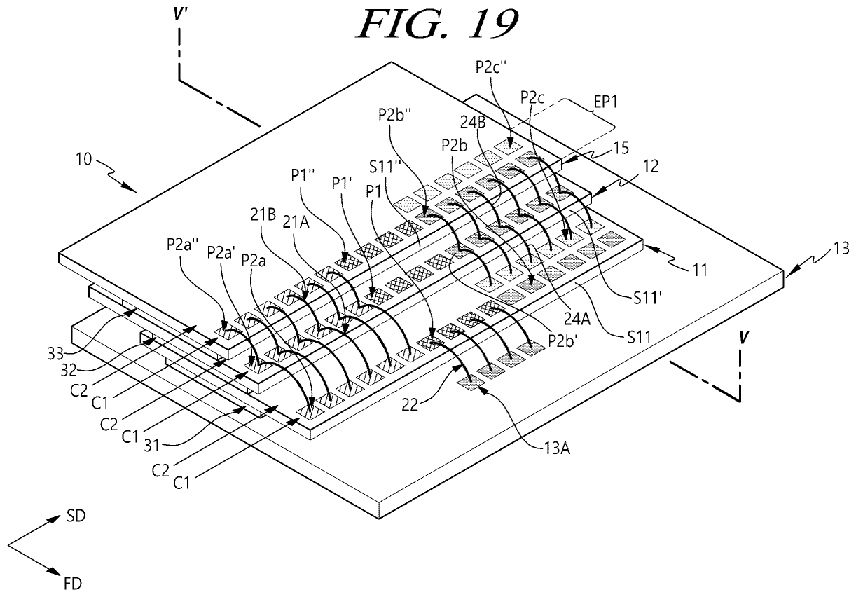

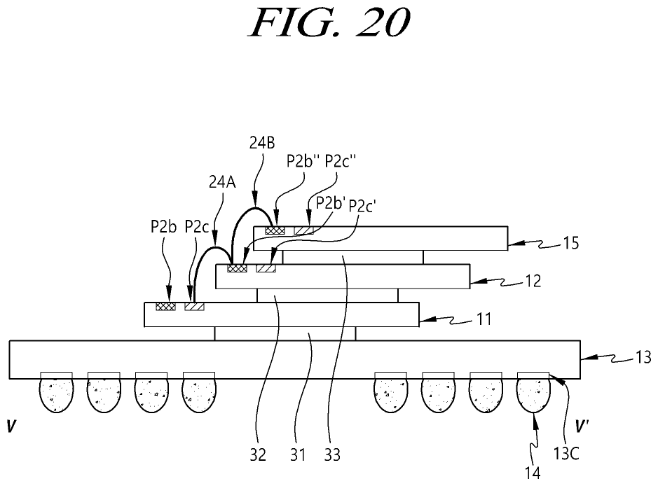

FIG. 19 is a perspective view illustrating an example of the semiconductor package, for example, as shown in FIG. 18, and FIG. 20 is a cross-sectional view taken along the line V-V′ of FIG. 19.

Referring to FIG. 19 and FIG. 20, compared to the semiconductor package of FIG. 16 and FIG. 17, the semiconductor package of FIG. 19 and FIG. 20 may further include the third chip 15, the fifth connection members 21B, and the sixth connection members 24B. The descriptions of components of FIG. 19 and FIG. 20 the same as components of FIG. 16 and FIG. 17 are described with respect to FIG. 16 and FIG. 17.

The third chip 15 is disposed on the second chip 12. A third adhesive layer 33 is disposed between the second chip 12 and the third chip 15 to attach the second chip 12 to the third chip 15.

The third chip 15 includes a first pad column C1 and a second pad column C2 that are located in a first edge section or portion EP1. The first pad column C1 among a plurality of pad columns of the third chip 15 is an outermost pad column that is closest to a first side surface S11″ of the first edge portion EP1. The second pad column C2 among the plurality of pad columns of the third chip 15 is a pad column that is next to the first pad column C1.

The external signal pads P1″, the slice data pads P2a″, and the slice command/address reception pads P2b″ are included in the first pad column C1 of the third chip 15, and the slice command/address transmission pads P2c″ are included in the second pad column C2 of the third chip 15.

As described with reference to FIG. 16 and FIG. 17, the second chip 12 is offset with respect to the first chip 11 and exposes or facilitates access to the first pad column C1 and the second pad column C2 of the first chip 11. The second chip 12 is offset with respect to the first chip 11 by a distance corresponding to at least two pad columns.

The third chip 15 is offset with respect to the second chip 12 and exposes or facilitates access to the first pad column C1 of the second chip 12 and covers or limits access to the second pad column C2 of the second chip 12. The third chip 15 is offset with respect to the second chip 12 by a distance corresponding to at least one pad column.

Because the second chip 12 is offset with respect to the first chip 11, the second chip 12 includes an overhang that is not supported by the underlying first chip 11. The width of the overhang of the second chip 12 is determined according to a distance by which the second chip 12 is offset from the first chip 11. For example, the overhang of the second chip 12 has a width corresponding to at least two pad columns.

Because the third chip 15 is offset with respect to the second chip 12, the third chip 15 includes an overhang that is not supported by the underlying second chip 12. The width of the overhang of the third chip 15 is determined according to a distance by which the third chip 15 is offset from the second chip 12. The overhang of the third chip 15 has a width corresponding to at least one pad column. The overhang of the third chip 15 may have a smaller width than the overhang of the second chip 12.

Each of the slice data pads P2a that are included in the first pad column C1 of the first chip 11 is connected to a different one of the slice data pads P2a′ that are included in the first pad column C1 of the second chip 12 by one of the first connection members 21A. The first connection members 21A may include bonding wires.

Each of the first connection members 21A connects the slice data pad P2a and the nearest or nearby slice data pad P2a′, where the second pad column C2 of the first chip 11 and the first side surface S11′ of the second chip 12 are interposed between the slice data pad P2a and the slice data pad P2a′.

Each of the slice command/address transmission pads P2c that are included in the second pad column C2 of the first chip 11 is connected to a different one of the slice command/address reception pads P2b′ that are included in the first pad column C1 of the second chip 12 by one of the fourth connection members 24A. The fourth connection members 24A may include bonding wires.

Each of the fourth connection members 24A connects the slice command/address transmission pad P2c and the nearest or nearby slice command/address reception pad P2b′, where the first side surface S11′ of the second chip 12 is interposed between the slice command/address transmission pad P2c and the slice command/address reception pad P2b′.

Each of the slice data pads P2a′ that are included in the first pad column C1 of the second chip 12 is connected to a different one of the slice data pads P2a″ that are included in the first pad column C1 of the third chip 15 by one of the fifth connection members 21B. The fifth connection members 21B may include bonding wires.

Each of the fifth connection members 21B connects the slice data pad P2a′ and the nearest or nearby slice data pad P2a″, where the first side surface S11″ of the third chip 15 is interposed between the slice data pad P2a′ and the slice data pad P2a″. The fifth connection member 21B may have a shorter length than the length of the first connection member 21A.

Each of the slice command/address reception pads P2b′ that are included in the first pad column C1 of the second chip 12 is connected to a different one of the slice command/address reception pads P2b″ that are included in the first pad column C1 of the third chip 15 by one of the sixth connection members 24B. The sixth connection members 24B may include bonding wires.

Each of the sixth connection members 24B connects the slice command/address reception pad P2b′ and the nearest or nearby slice command/address reception pad P2b″, where the first side surface S11″ of the third chip 15 is interposed between the slice command/address reception pad P2b′ and the slice command/address reception pad P2b″.

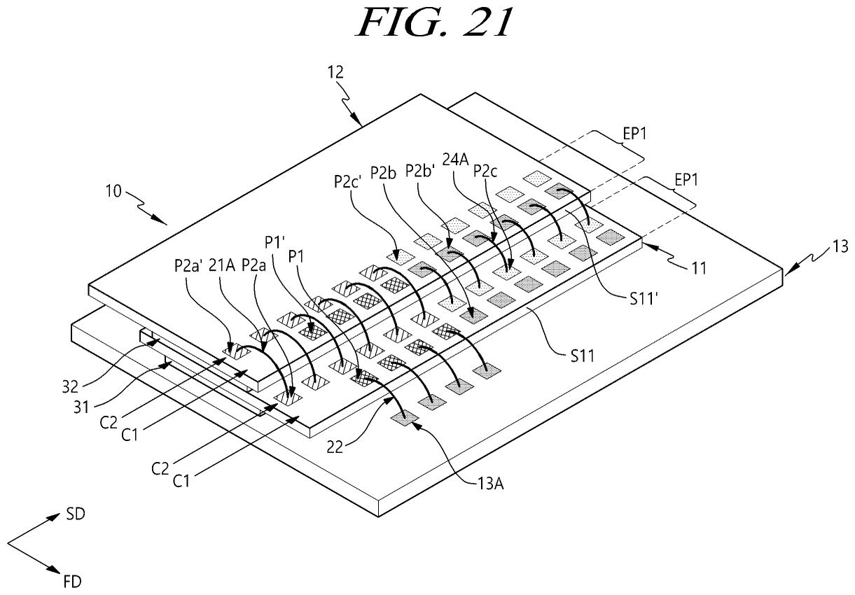

FIG. 21 is a perspective view illustrating an example of the semiconductor package 10, for example, as shown in FIG. 15.

Referring to FIG. 21, the external signal pads P1 and the slice command/address reception pads P2b are included in the first pad column C1 of the first chip 11, and the slice data pads P2a and the slice command/address transmission pads P2c are included in the second pad column C2 of the first chip 11.

For example, the external signal pads P1 are disposed in a region adjacent in the first direction FD to a region where the slice data pads P2a are disposed, and the slice command/address transmission pads P2c are disposed in a region adjacent in the first direction FD to a region where the slice command/address reception pads P2b are disposed.

The external signal pads P1′ and the slice command/address reception pads P2b′ are included in the first pad column C1 of the second chip 12, and the slice data pads P2a′ and the slice command/address transmission pads P2c′ are included in the second pad column C2 of the second chip 12.

For example, the external signal pads P1′ are disposed in a region adjacent in the first direction FD to a region where the slice data pads P2a′ are disposed, and the slice command/address transmission pads P2c′ are disposed in a region adjacent in the first direction FD to a region where the slice command/address reception pads P2b′ are disposed.

The second chip 12 is offset with respect to the first chip 11 and exposes or facilitates access to the first pad column C1 and the second pad column C2 of the first chip 11. The second chip 12 is offset with respect to the first chip 11 by a distance corresponding to at least two pad columns.

Each of the slice data pads P2a that are included in the second pad column C2 of the first chip 11 is connected to a different one of the slice data pads P2a′ that are included in the second pad column C2 of the second chip 12 by one of the first connection members 21A.

Each of the first connection members 21A connects the slice data pad P2a and the nearest or nearby slice data pad P2a′, where the first pad column C1 of the second chip 12 and the first side surface S11′ of the second chip 12 are interposed between the slice data pad P2a and the slice data pad P2a′.

Each of the slice command/address transmission pads P2c that are included in the second pad column C2 of the first chip 11 is connected to a different one of the slice command/address reception pads P2b′ that are included in the first pad column C1 of the second chip 12 by one of the fourth connection members 24A.

Each of the fourth connection members 24A connects the slice command/address transmission pad P2c and the nearest or nearby slice command/address reception pad P2b′, where the first side surface S11′ of the second chip 12 is interposed between the slice command/address transmission pad P2c and the slice command/address reception pad P2b′.

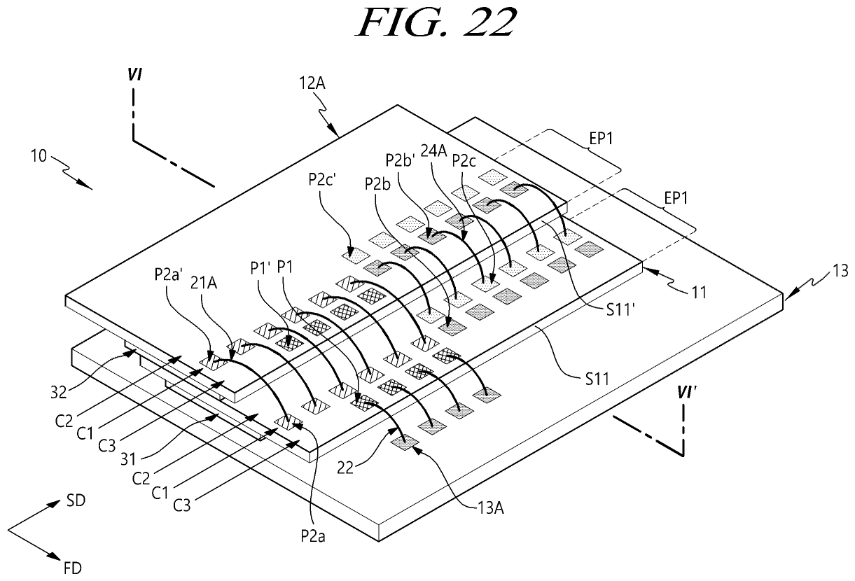

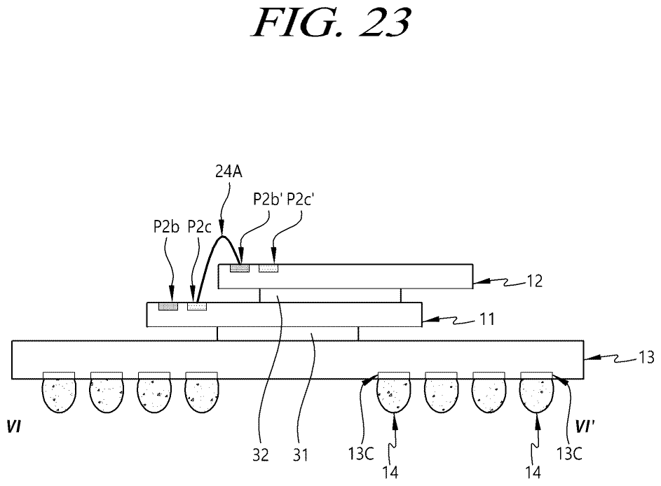

FIG. 22 is a perspective view illustrating an example of the semiconductor package, for example, as shown in FIG. 15, and FIG. 23 is a cross-sectional view taken along the line VI-VI′ of FIG. 22.

Referring to FIG. 22 and FIG. 23, each of the first and second chips 11 and 12 includes a first pad column C1, a second pad column C2, and a third pad column C3 that are located in a first edge section or portion EP1.

The third pad column C3 among a plurality of pad columns of the first chip 11 is an outermost pad column that is closest to the first side surface S11 of the first edge portion EP1. The first pad column C1 among the plurality of pad columns of the first chip 11 is a pad column that is next to the third pad column C3. The first pad column C1 is further away from the first side surface S11 of the first chip 11 than the third pad column C3 that is closest to the first side surface S11 among the plurality of pad columns of the first chip 11. The second pad column C2 among the plurality of pad columns of the first chip 11 is a pad column that is next to the first pad column C1 and is the furthest column from the first side surface S11 among the plurality of pad columns of the first chip 11.

The third pad column C3 among a plurality of pad columns of the second chip 12 is an outermost pad column that is closest to the first side surface S11′ of the first edge portion EP1. The first pad column C1 among the plurality of pad columns of the second chip 12 is a pad column that is next to the third pad column C3. The first pad column C1 is further away from the first side surface S11′ of the second chip 12 than the third pad column C3 that is closest to the first side surface S11′ among the plurality of pad columns of the second chip 12. The second pad column C2 among the plurality of pad columns of the second chip 12 is a pad column that is next to the first pad column C1 and is the furthest column from the first side surface S11′ among the plurality of pad columns of the second chip 12.

The external signal pads P1 are included in the third pad column C3 of the first chip 11, the slice data pads P2a and the slice command/address reception pads P2b are included in the first pad column C1 of the first chip, and the slice command/address transmission pads P2c are included in the second pad column C2 of the first chip 11.

For the first chip 11, the external signal pads P1 are disposed in a region adjacent in the first direction FD to a region where the slice data pads P2a are disposed, and the slice command/address transmission pads P2c are disposed in a region adjacent in the first direction FD to a region where the slice command/address reception pads P2b are disposed.

The external signal pads P1′ are included in the third pad column C3 of the second chip 12, the slice data pads P2a′ and the slice command/address reception pads P2b′ are included in the first pad column C1 of the second chip 12, and the slice command/address transmission pads P2c′ are included in the second pad column C2 of the second chip 12.

For the second chip 12, the external signal pads P1′ are disposed in a region adjacent in the first direction FD to a region where the slice data pads P2a′ are disposed, and the slice command/address transmission pads P2c′ are disposed in a region adjacent in the first direction FD to a region where the slice command/address reception pads P2b′ are disposed.

The second chip 12 is offset with respect to the first chip 11 and exposes or facilitates access to the first pad column C1, the second pad column C2, and the third pad column C3 of the first chip 11. The second chip 12 is offset with respect to the first chip 11 by a distance corresponding to at least three pad columns.

Each of the slice data pads P2a that are included in the first pad column C1 of the first chip 11 is connected to a different one of the slice data pads P2a′ that are included in the first pad column C1 of the second chip 12 by one of the first connection members 21A.

Each of the first connection members 21A connects the slice data pad P2a and the nearest or nearby slice data pad P2a′, where the first side surface S11′ of the second chip 12 and the third pad column C3 of the second chip 12 are interposed between the slice data pad P2a and the slice data pad P2a′.

Each of the slice command/address transmission pads P2c that are included in the second pad column C2 of the first chip 11 is connected to a different one of the slice command/address reception pads P2b′ that are included in the first pad column C1 of the second chip 12 by one of the fourth connection members 24A.

Each of the fourth connection members 24A connects the slice command/address transmission pad P2c and the nearest or nearby slice command/address reception pad P2b′, where the third pad column C3 of the second chip 12 and the first side surface S11′ of the second chip 12 are interposed between the slice command/address transmission pad P2c and the slice command/address reception pad P2b′.

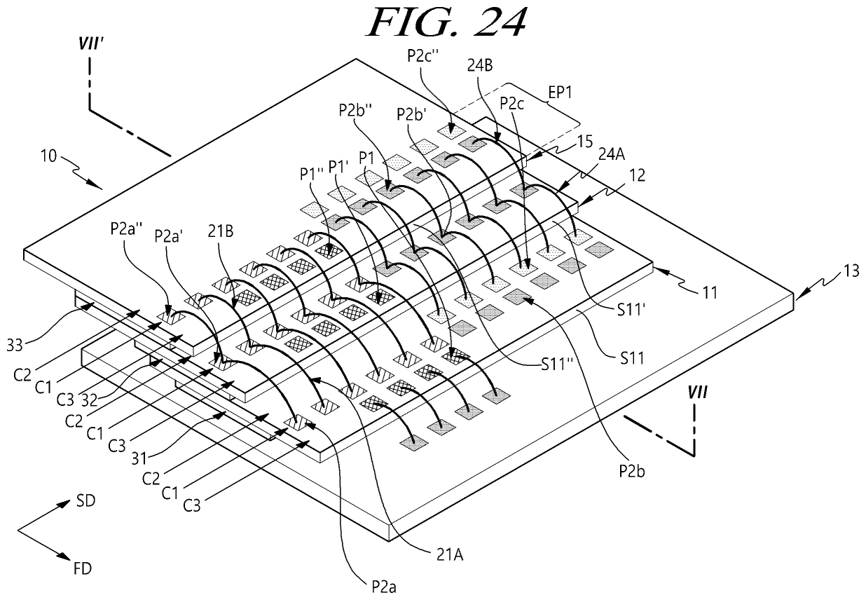

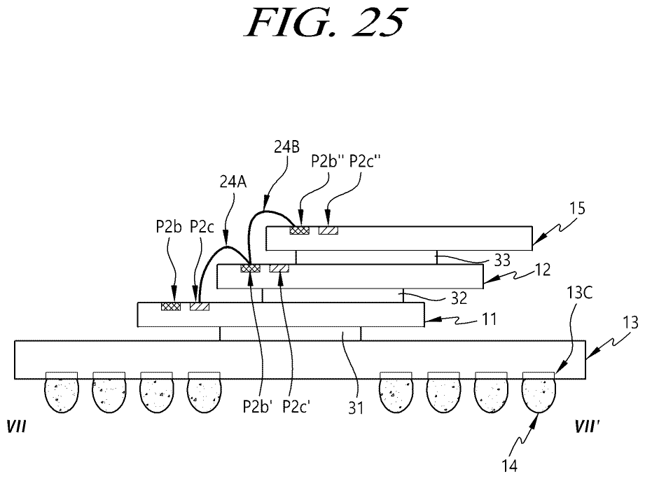

FIG. 24 is a perspective view illustrating an example of the semiconductor package, for example, as shown in FIG. 18, and FIG. 25 is a cross-sectional view taken along the line VII-VII′ of FIG. 24.

Referring to FIG. 24 and FIG. 25, compared to the semiconductor package 10 of FIG. 22 and FIG. 23, a semiconductor package 10 of FIG. 24 and FIG. 25 further includes a third chip 15, fifth connection members 21B, and sixth connection members 24B. The descriptions of components of FIG. 24 and FIG. 25 the same as components of FIG. 22 and FIG. 23 are described with respect to FIG. 22 and FIG. 23.

The third chip 15 is disposed on the second chip 12. A third adhesive layer 33 is disposed between the second chip 12 and the third chip 15 to attach the second chip 12 to the third chip 15.

The third chip 15 may have physically the same structure as the first chip 11 and the second chip 12. The third chip 15 may be the same type of chip as the first chip 11 and the second chip 12. The third chip 15 may be the same size as each of the first chip 11 and the second chip 12.

The third chip 15 includes a first pad column C1, a second pad column C2, and a third pad column C3 that are located in a first edge section or portion EP1.

The third pad column C3 among a plurality of pad columns of the third chip 15 is an outermost pad column that is closest to the first side surface S11″ of the first edge portion EP1. The first pad column C1 among the plurality of pad columns of the third chip 15 is a pad column that is next to the third pad column C3. The first pad column C1 is further away from the first side surface S11″ of the third chip 15 than the third pad column C3 that is closest to the first side surface S11″ among the plurality of pad columns of the third chip 15. The second pad column C2 among the plurality of pad columns of the third chip 15 is a pad column that is next to the first pad column C1 and is the furthest column from the first side surface S11″ among the plurality of pad columns of the third chip 15.

The external signal pads P1″ are included in the third pad column C3 of the third chip 15, the slice data pads P2a″ and the slice command/address reception pads P2b″ are included in the first pad column C1 of the third chip 15, and the slice command/address transmission pads P2c″ are included in the second pad column C2 of the third chip 15. The slice command/address transmission pads P2c′ are dummy pads in this example.

As described with reference to FIG. 22 and FIG. 23, the second chip 12 is offset with respect to the first chip 11 and exposes or facilitates access to the first pad column C1, the second pad column C2, and the third pad column C3 of the first chip 11. The second chip 12 is offset with respect to the first chip 11 by a distance corresponding to at least three pad columns.

The third chip 15 is offset with respect to the second chip 12 and exposes or facilitates access to the third pad column C3 and the first pad column C1 of the second chip 12 and covers or limits access to the second pad column C2 of the second chip 12. The third chip 15 is offset with respect to the second chip 12 by a distance corresponding to at least two pad columns.

Because the second chip 12 is offset with respect to the first chip 11, the second chip 12 includes an overhang that is not supported by the underlying first chip 11. The width of the overhang of the second chip 12 is determined according to a distance by which the second chip 12 is offset from the first chip 11. For example, the overhang of the second chip 12 has a width corresponding to at least three pad columns.

Because the third chip 15 is offset with respect to the second chip 12, the third chip 15 includes an overhang that is not supported by the underlying second chip 12. The width of the overhang of the third chip 15 is determined according to a distance by which the third chip 15 is offset from the second chip 12. For example, the overhang of the third chip 15 has a width corresponding to at least two pad columns. The overhang of the third chip 15 may have a smaller width than the width of the overhang of the second chip 12.

Each of the slice data pads P2a′ that are included in the first pad column C1 of the second chip 12 is connected to a different one of the slice data pads P2a″ that are included in the first pad column C1 of the third chip 15 by one of the fifth connection members 21B.

Each of the fifth connection members 21B connects the slice data pad P2a′ and the nearest or nearby slice data pad P2a″, where the third pad column C3 of the third chip 15 and the first side surface S11″ of the third chip 15 are interposed between the slice data pad P2a′ and the slice data pad P2a″.

Each of the slice command/address reception pads P2b′ that are included in the first pad column C1 of the second chip 12 is connected to a different one of the slice command/address reception pads P2b″ that are included in the first pad column C1 of the third chip 15 by one of the sixth connection members 24B.

Each of the sixth connection members 24B connects the slice command/address reception pad P2b′ and the nearest or nearby slice command/address reception pad P2b″, where the third pad column C3 of the third chip 15 and the first side surface S11″ of the third chip 15 are interposed between the slice command/address reception pad P2b′ and the slice command/address reception pad P2b″.

In one example, the master chip 11 includes a first plurality of pad columns disposed near or next to a first side S11 of the master chip 11. The first slave chip 12 comprises a second plurality of pad columns disposed near or next to a second side S11′ of the first slave chip 12. A second slave chip 15 is stacked on the first slave chip 12 and includes a third plurality of pad columns disposed near or next to a third side S11″ of the second slave chip 15. The second side S11′ of the first slave chip 12 is offset with respect to the first side S11 of the master chip 11 to facilitate access to the first plurality of pad columns of the master chip 11. The third side S11″ of the second slave chip 15 is offset with respect to the second side S11′ of the first slave chip 12 to facilitate access to at least some of the second plurality of pad columns of the first slave chip 12. Optionally, all pads of the master chip 11 are disposed in the first plurality of pad columns, all pads of the first slave chip 12 are disposed in the second plurality of pad columns, and all pads of the second slave chip 15 are disposed in the third plurality of pad columns. Two, three, or more pad columns may be included in each of the master chip 11, the first slave chip 12, and the second slave chip 15.

In the detailed description, functionally similar components among the components of the first chip and the components of the second chip are indicated by the same reference numerals for the sake of simplicity. Components indicated with the same reference numerals may not be completely identical.

Although embodiments of the present disclosure are described for illustrative purposes, those skilled in the art will understand that various modifications, additions, and substitutions related to these embodiments are possible without departing from the scope and spirit of the present disclosure. Therefore, the embodiments disclosed and shown in the accompanying drawings should be considered in a descriptive sense only without limiting the scope. The technological scope of the present disclosure is not limited by the embodiments and the accompanying drawings. All changes within the meaning and range of equivalency of the claims are included within their scope.

What is claimed is:

1. A semiconductor package comprising:
a substrate;
a first chip and a second chip stacked on the substrate, each of the first chip and the second chip including a slice command/address reception pad, a slice command/address transmission pad, a slice data pad, an input buffer connected to the slice command/address reception pad, an output buffer connected to the slice command/address transmission pad, and an input/output buffer connected to the slice data pad;
a first connection member connecting the slice command/address transmission pad of the first chip to the slice command/address reception pad of the second chip; and
a second connection member connecting the slice data pad of the first chip to the slice data pad of the second chip.

2. The semiconductor package according to claim 1, wherein in each of the first chip and the second chip, an input terminal of the input buffer is not connected to an output terminal of the output buffer.

3. The semiconductor package according to claim 1, wherein in each of the first chip and the second chip, a size of the output buffer is larger than a size of the input buffer.

4. The semiconductor package according to claim 1, wherein the first connection member and the second connection member comprise bonding wires.

5. The semiconductor package according to claim 1,
wherein each of the first chip and the second chip includes a first pad column and a second pad column that are located in a first edge section;
wherein the first pad column is located between a chip side surface included in the first edge section and the second pad column; and
wherein, in each of the first chip and the second chip, the slice command/address reception pad and the slice data pad are disposed in the first pad column, and the slice command/address transmission pad is disposed in the second pad column.

6. The semiconductor package according to claim 5, wherein
each of the first chip and the second chip further includes an external signal pad, and
the external signal pad is disposed in the first pad column.

7. The semiconductor package according to claim 5, wherein
the second chip is stacked on the first chip, and
the second chip is offset with respect to the first chip to expose the first pad column and the second pad column of the first chip.

8. The semiconductor package according to claim 7, further comprising:
a third chip stacked on the second chip;
a third connection member connecting the slice command/address transmission pad of the second chip to a slice command/address reception pad of the third chip; and
a fourth connection member connecting the slice data pad of the second chip to a slice data pad of the third chip.

9. The semiconductor package according to claim 8, wherein the third chip is offset with respect to the second chip to expose the first pad column of the second chip and cover the second pad column of the second chip.

10. The semiconductor package according to claim 1,
wherein each of the first chip and the second chip includes a first pad column and a second pad column that are located in a first edge section;
wherein the first pad column is located between a chip side surface and the second pad column; and
wherein, in each of the first chip and the second chip, the slice command/address reception pad is disposed in the first pad column, and the slice data pad and the slice command/address transmission pad are disposed in the second pad column.

11. The semiconductor package according to claim 10, wherein
each of the first chip and the second chip further includes an external signal pad, and
the external signal pad is disposed in the first pad column.

12. The semiconductor package according to claim 10, wherein
the second chip is stacked on the first chip, and
the second chip is offset with respect to the first chip to expose the first pad column and the second pad column of the first chip.

13. The semiconductor package according to claim 10,
wherein each of the first chip and the second chip further includes an external signal pad;
wherein the external signal pad is disposed in a third pad column; and
wherein the third pad column is located between a chip side surface and the first pad column.

14. The semiconductor package according to claim 13,
wherein each of the first chip and the second chip includes a plurality of pad columns;
wherein the third pad column among the plurality of pad columns is a pad column that is closest to a chip side surface;
wherein the first pad column is a pad column that is next to the third pad column; and
wherein the second pad column is a pad column that is next to the first pad column and is a pad column among the plurality of pad columns furthest from the chip side surface.

15. The semiconductor package according to claim 13, wherein
the second chip is stacked on the first chip, and
the second chip is offset with respect to the first chip to expose the first pad column, the second pad column, and the third pad column of the first chip.

16. A semiconductor package comprising:
a substrate;
a master chip and a slave chip stacked on the substrate, each of the master chip and the slave chip including a slice command/address reception pad, a slice command/address transmission pad, an input buffer connected to the slice command/address reception pad, and an output buffer connected to the slice command/address transmission pad; and
a first connection member connecting the slice command/address transmission pad of the master chip to the slice command/address reception pad of the slave chip.

17. The semiconductor package according to claim 16, wherein the output buffer of the master chip is load-decoupled from the output buffer of the slave chip.

18. A semiconductor package comprising:
a substrate;
a master chip stacked on the substrate and comprising a first slice command/address transmission pad connected to a first output buffer;
a first slave chip stacked on the master chip and comprising a second slice command/address reception pad connected to a second input buffer; and
a first connection member connecting the first slice command/address transmission pad to the second slice command/address reception pad.

19. The semiconductor package of claim 18, wherein the master chip includes a first plurality of pad columns disposed near a first side of the master chip, and wherein the first slave chip comprises a second plurality of pad columns disposed near a second side of the first slave chip, the semiconductor package further comprising:
a second slave chip stacked on the first slave chip and including a third plurality of pad columns disposed near a third side of the second slave chip;
wherein the second side of the first slave chip is offset with respect to the first side of the master chip to facilitate access to the first plurality of pad columns of the master chip; and
wherein the third side of the second slave chip is offset with respect to the second side of the first slave chip to facilitate access to at least some of the second plurality of pad columns of the first slave chip.

20. The semiconductor package according to claim 19, wherein all pads of the master chip are disposed in the first plurality of pad columns, all pads of the first slave chip are disposed in the second plurality of pad columns, and all pads of the second slave chip are disposed in the third plurality of pad columns.
